(19) United States
(12) Patent Application Publication
(10) Pub. No.: US 2026/0367919 A1
(43) Pub. Date: Nov. 19, 2026

(54) METHODS AND DEVICES FOR WORKLOAD BEHAVIORAL PHASE DETECTION

(71) Applicant: Intel Products IP LLC, Santa Clara, CA (US)

(72) Inventors: Przemyslaw R. KARPINSKI, Gdansk (PL); Jakub ATROSZKO, Gdynia (PL); Marcin KOSS, Trabki Wielkie (PL); Lukasz MELLER, Bojano (PL); Bartlomiej MICHALSKI, Gdynia (PL)

(21) Appl. No.: 19/719,249

(22) Filed: Jun. 25, 2026

(51) Int. Cl. G06F 9/38; G06F 9/50; G06F 30/20

(52) U.S. Cl. CPC G06F 9/38; G06F 9/5038; G06F 30/20

(57) ABSTRACT

A device including: a memory, and processor configured to: obtain time-series hardware performance data associated with an execution of a software workload on a physical processor; apply a state estimation filter to the time-series hardware performance data to generate a state vector for sequential time points during the execution; assign the sequential time points to distinct execution phases based on the state vector; and generate one or more machine-readable control instructions indicating execution boundaries corresponding to the distinct execution phases, wherein the one or more control instructions are configured to control execution modes of an architectural simulator.

### BACKGROUND

Architectural simulators are used to evaluate processor designs prior to fabrication by modeling the execution of a workload on a target processor microarchitecture and producing detailed performance metrics, including instructions per cycle, cache miss rates, and branch misprediction rates. For workloads of practical duration, including server database applications, video encoding workloads, and high-performance computing benchmarks, cycle-accurate simulation of the complete workload execution can require days or weeks of compute time.

This computational cost makes it impractical to evaluate multiple candidate processor designs by simulating each against a full workload. A standard approach to reduce simulation time is to identify representative portions of the workload that capture its characteristic execution behavior and to simulate only those portions, under the assumption that simulation of the representative portions produces results that closely approximate those obtained from simulating the complete workload.

### BRIEF DESCRIPTION OF THE DRAWINGS

In the drawings, like reference characters generally refer to the same parts throughout the different views. The drawings are not necessarily to scale, emphasis instead generally being placed upon illustrating the principles described herein. In the following description, various aspects are described with reference to the following drawings, in which:

FIG. 1 illustrates a block diagram of a computing system;

FIG. 2 illustrates a block diagram of a device according to various aspects described herein;

FIG. 3 illustrates a block diagram of a phase detection pipeline according to an example;

FIG. 4 illustrates a block diagram example of a hardware implementation pipeline for phase detection;

FIG. 5 illustrates measured hardware performance counter data for a client-server workload according to an example;

FIG. 6 illustrates reconstruction accuracy results for a compute-bound benchmark according to an example;

FIG. 7 illustrates reconstruction accuracy results for an input/output-bound benchmark according to an example;

FIG. 8 illustrates reconstruction accuracy results for a client-server database benchmark according to an example;

FIG. 9 illustrates feature evolution and phase classification data for a branch-misprediction metric according to an example;

FIG. 10 illustrates an example of a method.

### DESCRIPTION

The following detailed description refers to the accompanying drawings that show, by way of illustration, exemplary details and aspects in which aspects described herein may be practiced.

Various aspects described herein relates to devices, systems, and methods for generating instructions for an architectural simulator. They include, in particular, analyzing the execution behavior of software workloads on processors and for generating control data that guides architectural simulation of those workloads. More particularly, the disclosure relates to obtaining quantitative measurements from hardware performance monitoring units during workload execution, processing those measurements to identify distinct intervals of execution that exhibit stationary behavioral characteristics, and producing machine-readable control instructions that direct an architectural simulator to simulate selected portions of the workload at varying levels of fidelity.

The selection of representative portions involves three technical aspects. First, the computational cost of full cycle-accurate simulation is prohibitive for server workloads such as database systems and benchmark suites, making iterative architectural exploration impractical at cycle-accurate granularity. Second, software workloads exhibit distinct behavioral phases, for example, initialization, steady-state computation, input/output bursts, and communication or synchronization intervals, and identifying these phases from hardware performance counter measurements requires methods capable of handling noisy real-world measurements arising from operating system scheduling interference, measurement sampling granularity, and shared resource contention, as well as multi-metric correlations and variable phase durations. Third, once phases are identified, the architectural simulator requires precise machine-readable control instructions specifying, in terms of instruction counts, where each phase begins and for how long to simulate it. Existing approaches to phase identification have relied on code-based analysis that captures which code executes rather than how the processor microarchitecture behaves during execution, and may not account for measurement noise or multi-metric behavioral correlations.

Modern processors incorporate one or more performance monitoring units (PMUs), each comprising a set of hardware performance counters. Each hardware performance counter increments in response to a specified microarchitectural event during processor execution. Hardware performance counter metrics include, but are not limited to, instructions retired by the processor, unhalted reference clock cycles, unhalted thread cycles, level-one data cache replacements, branch mispredictions, and last-level cache misses. A PMU is typically programmed to read a selected group of counter metrics periodically, producing at each sampling interval a set of per-core counter values that together constitute one sample of the time-series hardware performance data for the executing workload. Example tools that collect and format hardware performance counter data include event monitor-(e.g., EMON-) compatible measurement utilities and IWPS-compatible measurement utilities. Because the PMU reads multiple event groups in sequence within each sampling interval, each group readout varies in interval and sample duration due to timing jitter. This jitter introduces variability in the raw per-interval counter values and is present in any downstream analysis of the time-series hardware performance data.

Architectural simulators model the execution of a software workload on a target processor microarchitecture and produce performance metrics without requiring physical fabrication of the processor. Architectural simulators operate at varying levels of fidelity: cycle-accurate simulators model every pipeline stage at each clock cycle, functional simulators model instruction effects without timing, and timing simulators approximate pipeline behavior using analytical models. A region of interest specification is a technique by which a simulator is directed to simulate only a designated portion of a workload, bounded by instruction counts indicating where the region begins and how many instructions to simulate. A cycle-accurate architectural simulator typically executes a software workload at a rate approximately 100,000 to 500,000 times slower than native processor execution, making full simulation of multi-minute workloads intractable. Both compute-bound workloads, such as floating-point benchmarks, and input/output-bound workloads, such as database systems and network servers, require phase-based sampling techniques to reduce simulation time while preserving the representativeness of simulation results.

A software workload exhibits distinct behavioral phases during its execution. Examples of execution phases include an initialization phase, during which data structures are loaded and processes are spawned; a steady-state computation phase, during which the workload performs its primary computational task; an input/output burst phase, during which data is transferred between processor memory and storage or network devices; and a communication or synchronization phase, during which cooperating processes or threads exchange data or wait for one another. These distinct execution phases may recur periodically throughout the workload execution trace. Identifying execution phases from hardware performance counter data is complicated by: i) operating system scheduling interference, which introduces transient changes in counter values unrelated to workload behavior; ii) measurement sampling granularity, which limits the temporal resolution of phase boundary detection; and iii) shared resource contention, which introduces variability across processor cores and co-located processes. In client-server workloads, the behavioral phases of the client process and the server process are coupled by application-level request-response interactions, requiring joint analysis of hardware performance counter data collected from both processes.

Existing phase detection approaches have used code-based feature vectors as the basis for phase identification. A code-based feature vector characterizes an interval of execution by the frequency distribution of visited code units, such as the relative frequency with which different blocks of executable code are executed during that interval. Clustering algorithms are then applied to the resulting collection of code-based feature vectors to partition the workload execution trace into phases. Code-based feature vectors capture which code executes but do not measure how the processor microarchitecture behaves while executing that code. In particular, they do not capture cache behavior, branch misprediction rates, or other microarchitectural effects that vary between execution intervals even when the same code executes. Furthermore, code-based approaches may apply cluster-count selection criteria that assume particular statistical distributions of the feature data, and they produce simulation-point indices rather than the instruction-count-based control instructions required by architectural simulators supporting region of interest specification. These characteristics limit the applicability of code-based approaches to phase detection based on hardware performance counter data.

In accordance with various aspects described herein, a device applies a state estimation filter to time-series hardware performance data to generate, for each of a sequence of successive time points during workload execution, a state vector comprising at least a filtered counter value and a trend estimate. The state estimation filter suppresses measurement noise arising from operating system scheduling interference, measurement sampling granularity, and/or shared resource contention, while preserving signatures of genuine phase transitions in the time-series hardware performance data. Because the filtered counter value and the trend estimate can be jointly maintained as components of the state vector at each time point, both are directly available for downstream processing without additional differentiation steps. The processor further assigns the sequential time points to distinct execution phases based on the state vector. In some aspects, the processor computes, for each time point, a multi-dimensional feature vector derived from the state vector. The processor may apply a clustering algorithm to the multi-dimensional feature vectors to assign each time point a cluster label, each distinct cluster label corresponding to a distinct execution phase. This feature-space approach enables detection of execution phases invisible to single-feature or code-based analysis, because the feature space captures the current level, the rate of change, the rate of change of the rate of change, overall dynamism in the state space, and local stability of the hardware performance counter metric.

In some aspects, the processor may determine the number of clusters applied by the clustering algorithm automatically by evaluating, for each candidate cluster count within a predefined range, a score measuring cluster cohesion and separation among the multi-dimensional feature vectors, and selecting the candidate cluster count that yields the highest score. The score may be a silhouette score or another measure of cluster cohesion and separation. This automated cluster-count selection can eliminate the need for manual phase identification and avoids distributional assumptions about the feature data. In some aspects, the processor generates machine-readable control instructions that express execution boundaries in instruction-count coordinates directly consumable by an architectural simulator supporting region of interest specification. The machine-readable control instructions may specify, for each execution phase, a warm-up interval followed by a detailed-simulation interval, each expressed as an instruction count. Direct generation of instruction-count-based control instructions eliminates additional tooling otherwise required to translate phase indices into simulator commands.

In a further aspect, the time-series hardware performance data comprises a plurality of hardware performance counter metrics, and each of them may be processed independently by the state estimation filter and the clustering algorithm. The cluster labels assigned per metric can be concatenated into a phase vector for each time point. Time points sharing an identical phase vector are assigned to the same execution phase. Through this multi-metric construction, cross-metric behavioral correlations invisible to single-metric analysis can be captured, enabling discrimination of execution phases that are identical in one metric but distinct in another. The combined application of state estimation filtering, multi-dimensional feature extraction, automated cluster-count selection, and multi-metric phase vector construction can enable a potential reduction in architectural simulation time across a broad range of approximately, for example approximately 6.8× to 194.8×, while achieving reconstruction correlation above, for example above 84% for short benchmarks with process-startup effects and above 99% for long-running server workloads. Reconstruction accuracy can be evaluated using normalized root mean square error, cross-correlation coefficient, dynamic time warping distance, and Kullback-Leibler divergence between the reconstructed estimated time-series and the time-series hardware performance data.

As used herein, the term “time-series hardware performance data” refers to an ordered sequence of quantitative measurements collected from hardware performance counters of a processor at successive sampling instants during execution of a software workload. In various aspects, the time-series hardware performance data may comprise per-core counter values collected independently for each processor core, aggregated values produced by summing the per-core values across a plurality of cores, or cumulated values produced by computing a running sum of the aggregated values over successive sampling instants. A hardware performance counter metric refers to a particular event type counted by a PMU, including but not limited to: instructions retired by the processor, level-one data cache replacements, branch mispredictions, unhalted reference clock cycles, unhalted thread cycles, and last-level cache misses.

A software workload refers to any executable program or set of cooperating programs that causes a processor to perform computation. In various aspects, a software workload may be a single-process application such as a high-performance computing benchmark or a media encoding application, a multi-process client-server application such as a database server communicating with one or more client processes, or a combination of cooperating programs executing on multiple processor cores or sockets. The term “physical processor” refers to a processor that executes the software workload natively, as opposed to a simulated processor model. The physical processor contains one or more cores, each equipped with a PMU. In various aspects, the physical processor may be a server processor, a desktop processor, or an embedded processor, and may be the same physical device as the processor performing phase analysis or a different device.

As used herein, the term “state estimation filter” refers to a recursive statistical filter that receives noisy observations and produces an estimate of an underlying state at each time point. The state estimation filter may operate by alternating between a prediction step, in which the state is extrapolated forward in time using a dynamical model, and an update step, in which the prediction is corrected using the current observation. The state estimation filter may be any Bayesian recursive filter. The state estimation filter may be a linear-Gaussian state-space filter. In a specific example, the state estimation filter is a Kalman filter; the state estimation filter may also be, or may include, an extended Kalman filter, an unscented Kalman filter, or a particle filter.

The term “state vector”, as used herein, refers to the vector of state variables maintained by the state estimation filter at a given time point. In various aspects described herein, the state vector comprises at least a filtered counter value and a trend estimate. A filtered counter value refers to the noise-suppressed estimate of the hardware performance counter value produced by the state estimation filter at a given time point, corresponding to the first component of the state vector. A trend estimate refers to the estimated rate of change, also termed the first derivative or velocity, of the hardware performance counter value, as maintained within the state vector of the state estimation filter.

An execution phase, as used herein, refers to a contiguous or non-contiguous temporal interval during workload execution during which hardware performance counter behavior is substantially stationary according to a classification criterion. Two time points belong to the same execution phase when their multi-dimensional feature vectors are assigned to the same cluster by the clustering algorithm. In various aspects, an execution phase may correspond to an initialization phase, a steady-state computation phase, an input/output burst phase, or a communication or synchronization phase. An execution phase is identified by a phase identifier, which is a discrete label uniquely distinguishing that phase within the workload execution trace. The term “execution boundary” refers to an instruction count or time offset that delimits the start or end of an execution phase within the workload execution trace. Execution boundaries are expressed in terms of instruction counts, providing a position metric that is independent of processor frequency and scheduling variability.

As used herein, the term “multi-dimensional feature vector” refers to a vector of N scalar features computed for a given time point from the state vector and/or quantities derived from the state vector, where N is an integer of at least two. In various aspects, N may range from two to twenty; in a specific example, N equals five. A clustering algorithm refers to an unsupervised partitioning algorithm that assigns each multi-dimensional feature vector to one of K groups, referred to as clusters, such that mean intra-cluster distance between feature vectors is minimized and mean inter-cluster distance is maximized. The clustering algorithm may be any partitioning or density-based clustering algorithm. The clustering algorithm may be a centroid-based clustering algorithm, in which each cluster is represented by its centroid feature vector. In a specific example, the clustering algorithm is a k-means clustering algorithm, in which cluster assignments and centroids are alternately updated until convergence.

As used herein, the term “cluster label” refers to a discrete identifier assigned to a time point by the clustering algorithm, indicating which cluster the time point's multi-dimensional feature vector belongs to. Each distinct cluster label corresponds to a distinct execution phase, such that all time points sharing the same cluster label are assigned to the same execution phase. As used herein, the term “silhouette score” refers to a metric that quantifies, for each data point, the difference between the mean intra-cluster distance from that point to all other points in the same cluster and the mean distance from that point to all points in the nearest other cluster, normalized by the larger of the two values, yielding a value in the interval [−1, 1], where a value approaching 1 indicates that the data point is well-matched to its own cluster and poorly matched to neighboring clusters. As used herein, the term “normalization”, in the context of multi-dimensional feature vectors, refers to scaling each dimension of the feature vector by subtracting a central-tendency statistic and dividing by a dispersion statistic. In a specific example, normalization is z-score normalization, also termed standardization, in which the mean is subtracted and the result is divided by the standard deviation, applied dimension-by-dimension.

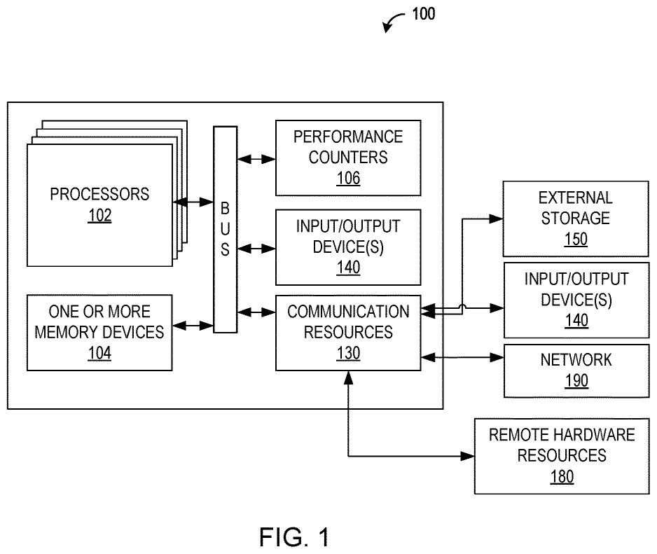

FIG. 1 illustrates a block diagram of an example computing system 100 in accordance with various aspects described herein. The computing system 100 typically includes a system of interconnected hardware and software resources configured to execute instructions, process data, and manage the allocation of computational capabilities. The computing system 100 may be a server, a workstation, a cluster of servers, a data center, or a cloud computing infrastructure. External storage 150, network 190, external input and output devices 140, and remote hardware resources 180 connect to the hardware resources via the communication resources 130 and input and output devices 140.

The computing system 100 generally includes one or more processors 102, one or more memory devices 104, a bus, communication resources 130, and one or more input/output devices 140. The processors 102 represent the computational core of the computing system 100 and each processor among the processors 102 integrates a cache hierarchy and a memory controller interface through which the processor 102 initiates memory transactions directed to the one or more memory devices 104.

The processors 102 may include one or more physical processing units. Each processing unit among the processors 102 may constitute a central processing unit, a microprocessor, a digital signal processor, or a graphics processing unit configured to perform general-purpose computing tasks. The processors 102 may include, for example, one or a combination of: a central processing unit (CPU), a reduced instruction set computing (RISC) processor, a complex instruction set computing (CISC) processor, a graphics processing unit (GPU), a DSP, an ASIC, an FPGA, a microprocessor or controller, a multi-core processor, a multithreaded processor, an ultra-low voltage processor, an embedded processor, an xPU, a data processing unit (DPU), an Infrastructure Processing Unit (IPU), a network processing unit (NPU), another processor (including any of those discussed herein), and/or any suitable combination thereof. Each processor among the processors 102 communicates with the one or more memory devices 104 through a memory controller that manages command scheduling, address mapping, rank selection, refresh management, and coordination of data transfers, incorporating timing control logic that enforces the temporal constraints imposed by the memory interface specification.

In some examples, the one or more processors 102 may execute instructions (e.g., non-transitory computer-readable instructions). Instructions may include software, program code, application(s), applet(s), an app(s), firmware, microcode, machine code, and/or other executable code for causing at least any one of the processors 102 to perform a method. The instructions may reside, completely or partially, within at least one of the processors 102 (e.g., within the processor's cache memory), the memory devices 104, or any suitable combination thereof. Furthermore, any portion of the instructions may be transferred to the computing system 100 from any combination of the input and/or output devices 140 or the external storage 150.

The one or more memory devices 104 provide the main storage for data and instructions that are actively used by the processors 102. The one or more memory devices 104 may include volatile memory technologies, such as dynamic random access memory, synchronous dynamic random access memory, or static random access memory. In high-performance configurations, the one or more memory devices 104 may include high bandwidth memory or double data rate synchronous dynamic random access memory. The one or more memory devices 104 can be organized into physical banks or modules, such as DIMMs. Each DIMM may be configured as an RDIMM including an RCD and a plurality of DRAM devices organized into one or more ranks, where the RCD is positioned electrically between the memory controller and the DRAM devices and buffers command, address, and clock signals as described herein. Within the context of the computing system 100, the one or more memory devices 104 may be distributed across different memory controllers associated with specific processors or specific non-uniform memory access nodes.

As examples, the memory devices 104 can be or can include random access memory (RAM), static RAM (SRAM), dynamic RAM (DRAM), synchronous DRAM (SDRAM), magnetoresistive RAM (MRAM), conductive bridge Random Access Memory (CB-RAM), spin transfer torque (STT)-MRAM, phase change RAM (PRAM), core memory, dual inline memory modules (DIMMs), microDIMMs, MiniDIMMs, block addressable memory device(s) (e.g., those based on NAND or NOR technologies (e.g., single-level cell (SLC), multi-level cell (MLC), quad-level cell (QLC), tri-level cell (TLC), or some other NAND), read-only memory (ROM), programmable ROM (PROM), erasable PROM (EPROM), electrically EPROM (EEPROM), flash memory, non-volatile RAM (NVRAM), solid-state storage, magnetic disk storage mediums, optical storage mediums, memory devices that use chalcogenide glass, multi-threshold level NAND flash memory, NOR flash memory, single or multi-level phase change memory (PCM) and/or phase change memory with a switch (PCMS), NVM devices that use chalcogenide phase change material (e.g., chalcogenide glass), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge random access memory (CB-RAM), or spin transfer torque (STT)-MRAM, a spintronic magnetic junction memory based device, a magnetic tunneling junction (MTJ) based device, a domain wall (DW) and spin orbit transfer (SOT) based device, a thyristor based memory device, and/or a combination of any of the aforementioned memory devices, and/or other memory.

The processors 102 and the one or more memory devices 104 communicate via a bus or an interconnect system. The bus represented in FIG. 1 generally illustrates the data pathways within the computing system 100. In practice, this bus may include a complex web of point-to-point interconnects, such as the ultra path interconnect or the quickpath interconnect. These interconnects facilitate high-speed data transfer between different processor sockets and between processors and memory controllers.

The memory interface between the memory controller and the one or more memory devices 104 operates at multi-gigahertz frequencies with timing margins measured in tens of picoseconds, requiring precise signal integrity management at every stage of the signal path; registered DIMMs are the standard module form factor in server and datacenter deployments of the computing system 100 where module capacity, signal integrity across densely populated channels, and reliability under sustained workloads are primary design requirements.

The communication resources 130 enable the computing system 100 to exchange data with external entities. The communication resources 130 may include one or more network interface controllers, host bus adapters, or input/output fabric interfaces. The network interface controllers may support various communication standards, such as Ethernet, InfiniBand, or Fibre Channel. The communication resources 130 manage the physical and data link layers of the communication protocols, handling the transmission and reception of data packets. The communication resources 130 connect the computing system 100 to a network 190. The network 190 may be a local area network, a wide area network, the internet, or a dedicated storage area network. Through the network 190, the computing system 100 may access remote hardware resources 180 and external storage 150. For example, the communication resources 130 may include wired communication components, cellular communication components, Wi-Fi components, and other communication components

The input/output devices 140 associated with the computing system 100 represent local peripheral interfaces and devices. These may include storage controllers, such as redundant array of independent disks controllers, universal serial bus controllers, and interfaces for human interaction devices like keyboards and monitors if the system is configured for direct user interaction. The input/output devices 140 may also include hardware accelerators, such as field-programmable gate arrays or application-specific integrated circuits, installed to offload specific processing tasks from the processors 102. The bus facilitates the communication between the processors 102 and the input/output devices 140, often utilizing standards like peripheral component interconnect express. FIG. 1 also illustrates input/output devices 140 external to the computing system 100, which may represent peripherals connected via the communication resources 130 or the network 190, providing flexibility in system configuration.

The external storage 150 represents persistent data storage repositories located outside the immediate physical chassis of the computing system 100. The external storage 150 may include storage area networks, network-attached storage systems, or cloud-based storage services. The external storage 150 may store application data and operating system files that are loaded into the one or more memory devices 104 during operation. The connection to the external storage 150 allows for centralized data management and facilitates features such as high availability, where a workload can be restarted on different hardware resources if the primary hardware fails. Access to the external storage 150 is mediated by the communication resources 130 and the protocols of the network 190, such as internet small computer systems interface or non-volatile memory express over fabrics.

The remote hardware resources 180 generally represent other computing nodes or clusters available via the network 190. In a distributed computing system 100, the computing system 100 may function as one physical node in a larger cluster, with the remote hardware resources 180 constituting the other physical nodes. The remote hardware resources 180 may possess similar or different configurations compared to the computing system 100. The ability to communicate with the remote hardware resources 180 enables distributed processing, where a single large task is decomposed into smaller sub-tasks executed in parallel across multiple machines.

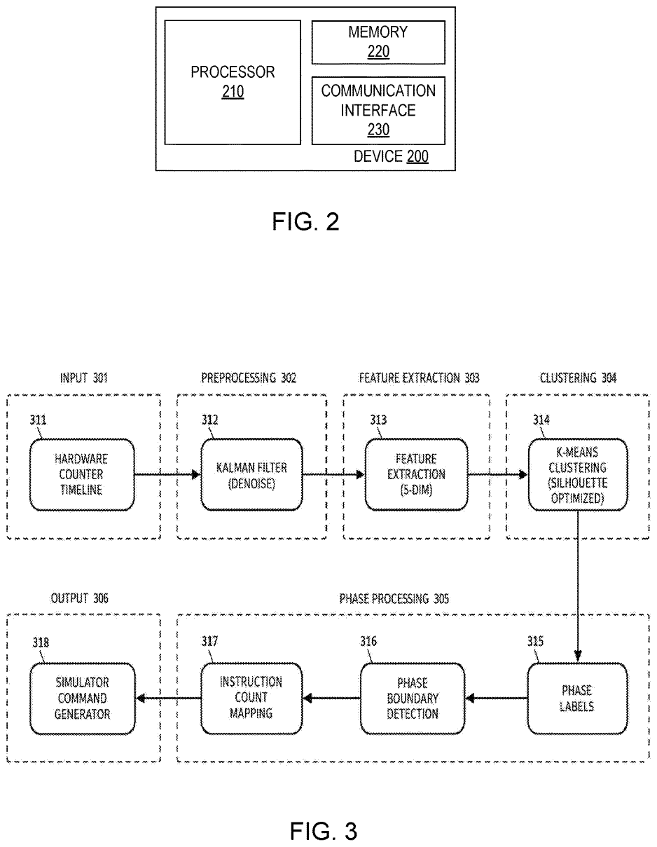

FIG. 2 is a block diagram of device 200, a device for workload phase detection. The device 200 comprises a processor 210, a memory 220, and a communication interface 230. The memory 220 stores instructions that, when executed by processor 210, cause processor 210 to perform the operations described herein. The device 200 may be embodied in any computing system, including the computing system 100. The processor 210 may be any of the processor types described in connection with the computing system 100, including but not limited to a central processing unit, a reduced instruction set computing processor, a complex instruction set computing processor, a graphics processing unit, a digital signal processor, an application-specific integrated circuit, a field-programmable gate array, a multi-core processor, a data processing unit, a network processing unit, or any suitable combination thereof. The communication interface 230 couples the device 200 to external entities including a physical processor, from which time-series hardware performance data is obtained, and an architectural simulator, which receives machine-readable control instructions produced by the processor 210. The physical processor is a processor that executes the software workload natively and whose PMU generates the time-series hardware performance data collected by the device 200.

The device 200 is configured to obtain time-series hardware performance data associated with execution of a software workload on the physical processor, to process the time-series hardware performance data through a phase detection pipeline to identify distinct execution phases of the software workload, and to generate one or more machine-readable control instructions indicating execution boundaries corresponding to the distinct execution phases. As used herein, the term “machine-readable control instructions” refers to data in a format parseable by an architectural simulator, specifying which portions of a software workload to simulate and at what level of fidelity. In various aspects, the machine-readable control instructions may be in the form of a command-line argument, a JavaScript Object Notation file, or a binary control stream. The term “architectural simulator” refers to a software or hardware system that models the execution of a software workload on a target processor microarchitecture. The architectural simulator may be a cycle-accurate simulator, a functional simulator with timing modes, or a full-system simulator. The architectural simulator may be configured to receive the machine-readable control instructions from the processor 210 and to simulate the software workload by switching between execution modes at the execution boundaries indicated by the machine-readable control instructions. The physical processor may be the same physical device as the processor 210. For example, where the device 200 performs phase detection on data produced by the processor that is also executing the analysis, or the physical processor may be a different physical device from the processor 210, for example, where the device 200 acts as a dedicated analysis unit for a separate workload-executing processor.

The device 200 may form part of a larger system for workload phase detection. In various aspects, such a system comprises one or more hardware components configured to collect time-series hardware performance counter data from physical processor executing a software workload; one or more processing units, which may be the same as or different from the physical processor, configured to apply a state estimation filter to the collected time-series hardware performance counter data, to assign sequential time points to distinct execution phases based on the resulting state vectors, and to generate one or more machine-readable control instructions indicating execution boundaries corresponding to the distinct execution phases; and an architectural simulator configured to receive the machine-readable control instructions and to simulate the software workload at varying fidelity levels according to the execution boundaries. The one or more processing units of the system may include the processor 210 of the device 200, dedicated digital logic within or adjacent to a PMU of the physical processor, or a combination of both, enabling distributed implementation of the phase detection computation across heterogeneous hardware components within the system.

FIG. 3 illustrates a processing flow in accordance with various aspects described herein. The processor 210 of the device may execute at least one, a combination of, or all described stages of the processing flow in accordance with certain aspects described herein. The processing flow, i.e., the phase detection pipeline 300, is depicted as a block diagram illustrating the sequence of processing stages applied to the time-series hardware performance data to produce the machine-readable control instructions for the architectural simulator. The pipeline 300 comprises, in processing order, an input stage 301, a preprocessing stage 302, a feature extraction stage 303, a clustering stage 304, a phase processing stage 305, and an output stage 306. Within the input stage 301, a hardware counter timeline block 311 may receive the time-series hardware performance data from the physical processor. The preprocessing stage 302 includes a Kalman filter block 312 that applies the state estimation filter to the incoming counter data. The feature extraction stage 303 houses a feature extraction block 313 that computes a multi-dimensional feature vector at each time point from the filtered state. The clustering stage 304 houses a k-means clustering block 314 that assigns a cluster label to each time point using silhouette-optimized cluster count selection. Within the phase processing stage 305, a phase labels block 315 organizes the assigned cluster labels, a phase boundary detection block 316 identifies transitions between distinct execution phases, and an instruction count mapping block 317 converts temporal phase boundaries into instruction-count execution boundaries. The output stage 306 houses a simulator command generator block 318 that produces the machine-readable control instructions from the instruction-count boundaries. The pipeline 300 may be implemented as a software pipeline executing on the processor 210, as dedicated digital logic within or adjacent to a PMU of the physical processor, or as a combination of software and hardware stages. A dedicated digital logic refers to a fixed-function or semi-programmable hardware unit, implemented within or adjacent to a processor's PMU, that performs state estimation filtering, feature computation, and phase classification in hardware, as distinct from general-purpose instruction execution on a processor core. The dedicated digital logic may be, or may include, a digital signal processing unit, an application-specific integrated circuit, or a field-programmable gate array co-located with the PMU.

The hardware counter timeline block 311 of the input stage 301 represents the entry point at which the processor 210 obtains time-series hardware performance data associated with execution of a software workload on the physical processor. The time-series hardware performance data is an ordered sequence of hardware performance counter measurements collected at successive sampling instants. The processor 210 may obtain the time-series hardware performance data from a stored log file produced by a measurement tool running on the physical processor, or the processor 210 may receive the time-series hardware performance data via a streaming interface from the PMU registers of the physical processor in real time. In an example, the measurement tool includes an EMON-compatible utility or an IWPS-compatible utility that samples the PMU of the physical processor at periodic intervals. The sampling interval may range from approximately 1 millisecond to approximately 10 seconds; in a preferred range, the sampling interval is from approximately 10 milliseconds to approximately 1 second; in a specific example, the sampling interval is approximately 100 milliseconds. Each sample collected at a given time point comprises a set of counter values, one per monitored hardware performance counter metric, quantifying the microarchitectural behavior of the physical processor during the preceding sampling interval.

The time-series hardware performance data obtained by the processor 210 may include measurements of one or more hardware performance counter metrics. Example metrics can include: instructions retired by the physical processor, which can be expressed as an INST_RETIRED.ANY_P counter value; level-one data cache replacements, expressed as an LID.REPLACEMENT counter value; branch mispredictions, expressed as a BR_MISP_RETIRED.ALL_BRANCHES counter value; unhalted thread clock cycles, expressed as a CPU_CLK_UNHALTED.THREAD_P counter value; unhalted reference clock cycles, expressed as a CPU_CLK_UNHALTED.REF_TSC counter value; and translation lookaside buffer load misses, expressed as a DTLB_LOAD_MISSES.STLB_HIT counter value. Each sample in the time-series hardware performance data may include a vector whose length equals the number of monitored hardware performance counter metric types. The time-series hardware performance data may include per-core counter values for each core of the physical processor. In an example, the processor 210 prepares the per-core counter values by summing the per-core counter values across a plurality of cores to produce a per-time-point aggregate value. The time-series hardware performance data may encompass a single hardware performance counter metric or a plurality of hardware performance counter metrics processed independently by the state estimation filter. Processing a plurality of hardware performance counter metrics independently enables detection of execution phases that differ across multiple metrics simultaneously, capturing cross-metric behavioral correlations of the software workload.

The Kalman filter block 312 of the preprocessing stage 302 represents the application, by the processor 210, of a state estimation filter to the time-series hardware performance data to generate a state vector for each of the sequential time points during execution of the software workload. The state estimation filter receives the noisy hardware performance counter observations and produces, at each time point, an estimate of the underlying state of the hardware performance counter metric. The state estimation filter may be any recursive Bayesian filter that alternates between a prediction step, in which the current state is extrapolated forward using a dynamical model, and an update step, in which the prediction is corrected by the current observation. A dynamical model, as described herein, refers to the mathematical model governing the predicted evolution of the state vector from one time point to the next. In various aspects, the dynamical model is a constant-velocity model in which the filtered counter value at a next time point is predicted as the sum of the current filtered counter value and the current trend estimate, expressible as x(t+1)=x(t)+v(t), where x(t) denotes the filtered counter value and v(t) denotes the trend estimate at time t. In a specific example, the constant-velocity dynamical model is encoded in a transition matrix F=[[1, 1], [0, 1]] and an observation matrix H=[[1, 0]]. The state estimation filter may be a linear-Gaussian state-space filter. In a specific example, the state estimation filter is a Kalman filter. The state estimation filter may also be, or may include, an extended Kalman filter, an unscented Kalman filter, or a particle filter, each accommodating varying degrees of non-linearity or non-Gaussianity in the underlying dynamical model. The processor 210 may apply the state estimation filter in an offline mode, processing a complete stored time-series, or in an online mode, updating the state estimate incrementally as each new time point is observed.

In an example in which the state estimation filter is a Kalman filter, the state vector xₜ=[vₜ, \dot{v}ₜ]^{T} comprises a filtered counter value vₜ, and a trend estimate \dot{v}ₜ. The dynamical model governing the prediction step is a constant-velocity model: xₜ₊₁=F*xₜ+wₜ, where the transition matrix F=[[1, 1], [0, 1]] predicts the next filtered counter value as the sum of the current filtered counter value and the current trend estimate, and predicts the next trend estimate as equal to the current trend estimate, and where wₜ is a zero-mean Gaussian process noise vector. The observation model governing the update step is: zₜ=H*xₜ+nₜ, where the observation matrix H=[[1, 0]] extracts the filtered counter value component of the state vector as the predicted observation, and nₜ is a zero-mean Gaussian observation noise scalar. Observation noise variance and process noise variance parameters may be derived from the time-series hardware performance data. For each successive time point, the Kalman filter iterates the prediction step and the update step, producing a state vector comprising a filtered counter value and a trend estimate at every time point. The state covariance matrix Pₜ, also maintained by the Kalman filter, quantifies the uncertainty in the state estimate at each time point and governs the weighting between the model prediction and the new observation during the update step.

An example of a 1-D Kalman filter, via a use of an existing Python pykalman library with the input mapping as described herein may be as follows:

```
def kalman_filter_1D(data):
  “““Apply Kalman filter modeling value and trend.”””
  initial_trend = numpy.mean(numpy.diff(data[:5]))
  initial_state_mean = [data[0], initial_trend]
  obs_var = numpy.var(data)
  trans_var = 0.01 * obs_var
  kf = KalmanFilter(
    transition_matrices=[[1, 1], [0, 1]],
    observation_matrices=[[1, 0]],
    initial_state_mean=initial_state_mean,
    initial_state_covariance=numpy.eye(2),
    observation_covariance=obs_var,
    transition_covariance=trans_var * numpy.eye(2)
  )
  state_means, state_covariances = kf.filter(data)
  return state_means, state_covariances
```

The feature extraction block 313 of the feature extraction stage 303 and the k-means clustering block 314 of the clustering stage 304 together implement the assignment, by the processor 210, of the sequential time points to distinct execution phases based on the state vectors generated by the state estimation filter. The processor 210 may partition the temporal sequence of state estimates by deriving a scalar feature from the filtered counter value component alone and applying a threshold-based or centroid-based classifier. The processor 210 may derive a multi-dimensional feature vector comprising features derived from both the filtered counter value and the trend estimate components of the state vector, and apply an unsupervised partitioning algorithm to the multi-dimensional feature vectors. In an example, the processor 210 computes a five-dimensional feature vector at each time point from the state vector and applies a k-means clustering algorithm with silhouette-optimised cluster count selection to assign each time point a cluster label identifying its execution phase for the corresponding hardware performance counter metric. The processor 210 may apply the clustering algorithm independently to the feature vectors derived from a single hardware performance counter metric. The processor 210 may apply the clustering algorithm independently per metric and concatenate the per-metric cluster labels into a phase vector that uniquely identifies workload-level execution phases across all monitored hardware performance counter metrics, as described herein.

An example of a feature vector constructed as described herein may include the following:

| Feature | Formula | Intuition |
|---|---|---|
| Value | f₁(t) = \hat{vₜ} | Filtered counter value |
| Velocity | f₂(t) = \hat{\dot{v}ₜ} | Rate of change (trend) |
| Acceleration | f₃(t) = \dot{\hat{v}}ₜ − \dot{\hat{v}}ₜ₋₁ | Trend change rate |
| State Speed | f₄(t) = \|xₜ − xₜ₋₁\| | State space movement |
| Rolling Variance | f₅(t) = Var(\hat{v}_{t-w:t}) | Local variability (window w = 5) |

In an example, the multi-dimensional feature vector for each time point t comprises at least two of the five scalar features in the table above. The first feature is the filtered counter value from the state vector, representing the denoised current level of the hardware performance counter metric. The second feature is the trend estimate from the state vector, representing the instantaneous rate of change of the hardware performance counter metric. The third feature is the difference between the trend estimate at the current time point and the trend estimate at the immediately preceding time point, representing the acceleration of the metric. The fourth feature is the Euclidean norm of the vector comprising the difference in the filtered counter value and the difference in the trend estimate between the current and immediately preceding time points, representing the overall speed of movement through the two-dimensional state space. The fifth feature is the variance of the filtered counter values within a sliding window of consecutive time points ending at the current time point, representing local stability of the metric. The sliding window size w may range from 2 to 20 time points; in a preferred range, w is from 3 to 10; in a specific example, w is 5.

An example code for Feature extraction from Kalman States with selected features can be as follows:

```
def calculate_features_from_kalman(state_means):
  “““Extract 5-dimensional feature vector from Kalman states.”””
  feature_labels = [‘Value’, ‘Velocity’, ‘Acceleration’, ‘State Speed’,
    ‘Rolling Variance’]
  feature_vectors = [ ]
  w = 5 # Rolling variance window
  for t in range(len(state_means)):
    feature_t = [
```

| | |
|---|---|
| state_means[t][0], | # Value |
| state_means[t][1], | # Velocity |
| state_means[t][1] − state_means[t−1][1], | # Acceleration |
| numpy.linalg.norm(state_means[t] − state_means[t−1]), | # State Speed |
| numpy.var(state_means[max(0, t−w):t+1, 0]), | # Rolling Variance |

```
    ]
    feature_vectors.append(feature_t)
  # Z-score normalization
  scaler = sklearn.preprocessing.StandardScaler( )
  features_scaled = scaler.fit_transform(numpy.array(feature_vectors))
  return features_scaled, feature_labels
```

The phase processing stage 305 implements the derivation of execution boundaries from the cluster labels assigned by the clustering stage 304. The phase labels block 315 may organize the cluster labels assigned by the k-means clustering block 314. For a given hardware performance counter metric, each time point's cluster label constitutes that time point's cluster label for that metric. Where the time-series hardware performance data comprises a plurality of hardware performance counter metrics, the processor 210 applies the state estimation filter independently to each metric and assigns a cluster label to each time point for each metric. The cluster labels across all metrics at a given time point are concatenated to form the phase vector for that time point. All time points sharing an identical phase vector are assigned the same phase identifier and belong to the same distinct execution phase. The phase boundary detection block 316 identifies successive time points at which the phase vector changes value, marking those positions as execution boundaries between distinct execution phases. The instruction count mapping block 317 translates the temporal execution boundaries into instruction-count positions using the cumulated retired-instruction counter values, specifically the INST_RETIRED.ANY_P counter, as the position metric, providing execution boundaries that are independent of wall-clock time and processor frequency.

An example code of a silhouette-optimized K-means as described herein for the clustering stage may be as the following:

```
def optimal_k_silhouette(data, k_range=range(2, 10)):
  “““Find optimal k using silhouette score.”””
  best_score = −1
  opt_clusters = k_range[0]
  for k in k_range:
    model = sklearn.cluster.KMeans(n_clusters=k, n_init=‘auto’).fit(data)
    if len(set(model.labels_)) > 1:
      score = sklearn.metrics.silhouette_score(data, model.labels_)
    else:
      score = −0.99 # Degenerate case
    if score > best_score:
      best_score = score
      opt_clusters = k
      best_model = model
  return opt_clusters, best_model, best_score
```

The simulator command generator block 318 of the output stage 306 represents the generation, by the processor 210, of one or more machine-readable control instructions indicating execution boundaries corresponding to the distinct execution phases. The machine-readable control instructions are data in a format directly parseable by the architectural simulator. The processor 210 may generate the machine-readable control instructions as a command-line argument string, a JavaScript Object Notation file, or a binary control stream. In a specific example, the machine-readable control instructions comprise a JavaScript Object Notation structure containing a phase_offsets entry in which each key is a phase vector string and each value specifies the sample range, start instruction count, and end instruction count for the corresponding execution phase. An instruction count refers to the number of instructions committed, also termed retired, by the physical processor during workload execution, used as a position metric within the workload execution trace that is independent of wall-clock time and unaffected by processor frequency variation or operating system scheduling. For instance, a phase vector “1, 0, 2, 0, . . . ” may correspond to a phase occupying samples 0 through 45 with a start instruction count of 0 and an end instruction count of 4,500,000,000 retired instructions. The processor 210 generates one entry per distinct execution phase in the phase_offsets structure, providing all information needed by the architectural simulator to locate and bound each representative simulation interval. This JavaScript Object Notation output is stored for post-simulation use in reconstruction and validation, as described in further detail below with reference to reconstruction embodiments.

An example samples mapping to a phase vector may be as the following, considering: For each PMU metric, a metric-local phase is identified. All metric-local phases for a particular sample can be concatenated into a Phase Vector. The Phase Vector uniquely identifies the phase class for the sample. Samples that have the same Phase Vector correspond to the same measurable PMU characteristics-measuring characteristics of one sample of the class is equivalent to measuring all of them:

| Sample | | | | | | Phase |
|---|---|---|---|---|---|---|
| ID | INST_RETIRED | L1D.REPLACEMENT | CPU_CLK | . . . | Phase Vector | ID |
| 0 | 1 | 0 | 2 | . . . | (1, 0, 2, . . . ) | 0 |
| 1 | 1 | 0 | 2 | . . . | (1, 0, 2, . . . ) | 0 |
| 2 | 1 | 1 | 2 | . . . | (1, 1, 2, . . . ) | 1 |
| . . . | . . . | . . . | . . . | . . . | . . . | |
| N | 0 | 1 | 0 | . . . | (0, 1, 0, . . . ) | 4 |

The machine-readable control instructions generated by the processor 210 cause the architectural simulator to switch between execution modes at the instruction-count positions specified as execution boundaries. As used herein, the term “execution modes” refers to distinct simulation fidelity levels selectable by the machine-readable control instructions. The execution modes available to the architectural simulator include a warm-up mode in which the architectural simulator executes instructions at reduced fidelity to initialize microarchitectural state such as caches and branch predictors, a detailed-simulation mode in which the architectural simulator executes instructions at full cycle-accurate fidelity, and a fast-forward mode. In the warm-up mode, the architectural simulator executes instructions at reduced fidelity to initialize microarchitectural state, including cache contents and branch-predictor state, to a condition representative of the corresponding point in native execution. In the detailed-simulation mode, the architectural simulator executes instructions at full cycle-accurate fidelity, collecting timing and performance metrics representative of the corresponding execution phase. In the fast-forward mode, the architectural simulator executes instructions functionally without collecting timing data. In an example, the processor 210 generates the machine-readable control instructions as a command-line argument string of the form “control:start:icount:S, warmup:icount:W1, detailed:icount:D1, warmup:icount:W2, detailed:ico unt:D2, . . . , stop”, where S is the start instruction count, W1 and D1 are the warm-up and detailed-simulation instruction counts for the first representative phase, and subsequent warmup-detailed pairs correspond to subsequent representative phases. The warm-up mode is preferred over the fast-forward mode because the warm-up mode achieves improved simulation fidelity at negligible additional simulation time overhead, by priming the microarchitectural state of the architectural simulator before the detailed-simulation interval commences. A detailed-simulation interval refers to a number of instructions that the architectural simulator executes at full cycle-accurate fidelity within an execution phase, collecting timing and performance data representative of that phase.

An example of phase information about specific phases detected, their offsets, and duration (e.g., in JSON format) may be as follows:

```
{
  “phase_labels_client”: {
    “INST_RETIRED.ANY_P”: [1, 1, 1, 2, 2, 2, 0, 0, ...],
    “L1D.REPLACEMENT”: [0, 0, 1, 1, 1, 2, 2, 2, ...],
    “CPU_CLK_UNHALTED.THREAD_P”: [2, 2, 2, 1, 1, 0, 0, 0, ...]
  },
  “phase_labels_server”: {
    “INST_RETIRED.ANY_P”: [0, 0, 0, 1, 1, 1, 2, 2, ...],
    ...
  },
  “phase_ranges”: {
    “1,0,2,0,...”: [[0, 45], [120, 180]],
    “2,1,1,1,...”: [[46, 119]],
    ...
  },
  “phase_offsets”: {
    “1,0,2,0,...”: [[0, 45], 0, 4500000000],
    “2,1,1,1,...”: [[46, 119], 4500000000, 7300000000],
    ...
  }
}
```

An example execution command generated for the IWPS simulator, for an FFT example, as described herein may be as follows, in which the simulator is instructed to sample specific intervals in detailed mode and lower accuracy for intermediate regions (warmup) and the instruction offsets can be calculated from phase-representative samples obtained during hardware execution data and the phase detection mechanism:
>run-iwps-c spr-c core/hook_periodic_ins/ins_global=0.0--disabled-cores=1-56-d iwps_fft_p1_m22_spr_1_9 GHz-s roi-control:start:icount:0.0, warmup:icount:91905002.0, detailed:icount:183512091.0, warmup:icou nₜ:91756045.0,detailed:icount:366328951.0, warmup:icount:91408430.0, detailed:icount:2221 02162.0, warmup:icount:78570604.0, detailed:icount:153070925.0,warmup:icount:75857081.0, detailed:icount:341738942.0, warmup:icount:98828379.0, detailed:icount:49414190.0, warmup: icount:94683537.0, detailed:icount:0.0, warmup:icount:93784562.0, detailed:icount:0.0, warmu p:icount:86971111.0, detailed:icount:0.0,warmup:icount:75825286.0, detailed:icount:0.0,warm up:icount:86031206.0, detailed:icount:0.0, warmup:icount:86182998.0, detailed:icount:0.0, war mup:icount:86097136.0, detailed:icount:0.0, warmup:icount:85931677.0, detailed:icount:0.0,wa rmup:icount:86298797.0, detailed:icount:0.0, warmup:icount:86317138.0, detailed:icount:2150 74155.0,warmup:icount:86008580.0, detailed:icount:43004291.0, warmup:icount:86220450.0, detailed:icount:1311657437.0, warmup:icount:85990761.0, detailed:icount:1295605675.0, war mup:icount:93327196.0, detailed:icount:46663599.0, warmup:icount:88193028.0, detailed:icou nₜ:43751322.0, warmup:icount:87502643.0, detailed:icount:43751322.0, warmup:icount:87562 626.0,detailed:icount:43670529.0, warmup:icount:87341059.0, detailed:icount:43670530.0, war mup:icount:87319244.0, detailed:icount:87369880.0, warmup:icount:87369879.0, detailed:icou nₜ:1003428973.0, warmup:icount:87195398.0,detailed:icount:897769684.0, warmup:icount:78 304398.0,detailed:icount:156608798.0, warmup:icount:86812854.0, detailed:icount:0.0, warmu p:icount:87166187.0,detailed:icount:88026928.0, warmup:icount:88026927.0, detailed:icount: 182178211.0:icount:92150443.0,stop

The processor 210 uses time-series hardware performance counter data, i.e., measuring microarchitectural events such as cache replacements, branch mispredictions, memory bandwidth utilization, and unhalted clock cycles directly at the physical processor, to identify distinct execution phases of the software workload. Code-based phase detection approaches characterize each execution interval by which blocks of code are visited during that interval rather than by the microarchitectural consequences of executing that code. A code-based approach assigns the same phase whenever the same code executes, regardless of whether the processor's caches are warm or cold, whether branch predictors have converged, or whether shared resources are contended. The hardware performance counter approach taken by the processor 210 directly measures these microarchitectural effects and can therefore identify execution phases that appear identical from a code-execution perspective but differ in measurable microarchitectural behavior. For example, two execution intervals that execute the same sequence of instructions may occupy different execution phases if one interval incurs high last-level cache miss rates due to cold-cache startup effects while the other incurs low miss rates during steady-state execution. The hardware performance counter data may be collected by the PMU of the physical processor during native execution and therefore reflects the actual microarchitectural dynamics of the software workload on the target hardware platform, enabling phase boundaries that correspond to genuine microarchitectural behavioral changes.

The state estimation filter applied by the processor 210 provides three specific capabilities beyond simpler signal conditioning. First, the state estimation filter achieves optimal state estimation in the presence of noise by combining the dynamical model's prediction with the current noisy observation through a gain that weights each source according to its estimated reliability. Approaches that apply clustering to raw or minimally processed counter values may assign different cluster labels to time points belonging to the same execution phase due to transient noise from operating system scheduling interference, measurement sampling jitter, or shared resource contention; the state estimation filter suppresses such transient fluctuations to produce cluster-label assignments that reflect genuine phase membership. Second, the state estimation filter produces a trend estimate, e.g., the estimated rate of change of the counter value, as a first-class component of the state vector at every time point, without requiring a separate differentiation step. This trend estimate is directly available as a feature dimension in the multi-dimensional feature vector, capturing the direction and rate of behavioral change that raw counter values do not convey. Third, by smoothing the counter time-series through the dynamical model, the state estimation filter suppresses spurious phase transitions caused by transient noise spikes, producing execution boundaries that correspond to genuine changes in workload behavior rather than measurement artefacts.

In an example, the multi-dimensional feature vector computed by the processor 210 at each time point captures five distinct dimensions of the behavioral state of the hardware performance counter metric, here identified by informal labels for clarity. The first dimension is the filtered counter value, such as the current denoised level of the metric. The second dimension is the trend estimate, such as the rate of change of the metric level, capturing the direction in which the metric is currently moving. The third dimension is the difference between the trend estimate at the current time point and the trend estimate at the immediately preceding time point, such as the acceleration, representing how rapidly the rate of change is itself changing, which is particularly sensitive to phase transitions. The fourth dimension may be the Euclidean norm of the vector comprising the differences in the filtered counter value and the trend estimate between the current and immediately preceding time points, such as the state speed, representing the overall magnitude of movement through the two-dimensional state space. The fifth dimension is the variance of the filtered counter values within a sliding window of consecutive time points ending at the current time point, such as the rolling variance, representing local stability. This five-dimensional representation enables detection of execution phases that have similar counter levels but differ in dynamics, for example, two intervals with similar mean values but diverging trends, which single-feature or code-based representations cannot discriminate.

In an example, the processor 210 determines the number of distinct execution phases automatically by evaluating the silhouette score for each candidate cluster count within a predefined range and selecting the candidate cluster count yielding the highest silhouette score. The silhouette score for a given candidate cluster count measures, for each data point in the normalized feature space, how well that point matches its assigned cluster relative to the nearest other cluster, without assuming any particular statistical distribution of the feature data. The predefined range of candidate cluster counts spans from a minimum of 2; the maximum of the range may be up to 50, for example up to 15, for example up to 9. For each candidate cluster count K within the predefined range, the processor 210 applies the clustering algorithm to the normalized multi-dimensional feature vectors, computes the resulting silhouette score, and retains the candidate count that yields the highest silhouette score observed across all evaluated counts. In a degenerate case where the clustering algorithm assigns all data points to a single cluster label, the silhouette score is set to a minimum value, for example −0.99, to prevent selection of that candidate count. In an alternative implementation, the processor 210 may use a bisection-based search over the candidate range to reduce the number of clustering evaluations required, since the silhouette score is an approximately smooth function of K. In a further alternative, the upper bound of the candidate range may be established using principal component analysis to estimate the maximum number of distinguishable phases from the data dimensionality.

In an example, the processor 210 may generate the machine-readable control instructions in a format specifying instruction-count offsets and durations directly consumable by the architectural simulator, without requiring intermediate conversion tooling. The processor 210 may derive execution boundaries from the cumulated values of the INST_RETIRED.ANY_P retired-instruction counter collected as part of the time-series hardware performance data, producing instruction-count positions that correspond precisely to positions within the native execution trace of the software workload on the physical processor. A retired-instruction counter refers to a specific hardware performance counter that increments for each instruction committed by the processor; in a specific example, the retired-instruction counter corresponds to the INST_RETIRED.ANY_P performance monitoring event. For each distinct execution phase, the processor 210 selects a representative time point to represent that phase. As used herein, the term “representative time point” refers to a single time point selected from within an execution phase to represent the entire phase in a reduced simulation. The representative time point may be selected according to one or more selection criteria, including but not limited to: the earliest-occurring time point within that phase, which corresponds to the minimal sample identifier within that phase; a centroid-nearest sample, which corresponds the time point whose multi-dimensional feature vector lies closest to the centroid of the corresponding cluster; a highest-confidence sample, which corresponds to the time point exhibiting the greatest separation from neighboring clusters in the feature space; a sample lying outside a transition or noise window adjacent to a phase boundary; an earliest sample satisfying a stability criterion applied to the state vector or the multi-dimensional feature vector; or a representative range selected to minimize a total simulation end offset subject to one or more quality constraints. The processor further derives the instruction-count start position and duration for that representative from the cumulated INST_RETIRED.ANY_P values at the boundaries of the representative's sample interval. In an example in which the earliest-occurring time point within each phase is selected as the representative time point, selecting the earliest representative per phase ensures that the end of the last representative sample occurs as early as practicable in the workload execution trace, enabling earlier termination of the simulation run and maximizing simulation time reduction for long-running workloads such as server applications. The processor 210 may assemble the per-phase instruction-count start positions, warm-up durations, and detailed-simulation durations into the machine-readable control instructions in a format, such as the command-line argument string or JavaScript Object Notation structure, that the architectural simulator can consume directly without additional processing.

The end-to-end operation of the device 200 through the phase detection pipeline 300 may proceed as follows. The processor 210 obtains the time-series hardware performance data from the physical processor, e.g., via the communication interface 230, either from a stored measurement log or through a real-time streaming interface. The processor 210 may apply the state estimation filter to the time-series hardware performance data to generate, for each sequential time point, a state vector comprising a filtered counter value and a trend estimate. From each state vector, the processor 210 may compute a multi-dimensional feature vector, normalize the multi-dimensional feature vectors dimension-by-dimension, and apply the clustering algorithm with automatically selected cluster count to assign each time point a cluster label. Where the time-series hardware performance data comprises multiple hardware performance counter metrics, the processor 210 performs state estimation and clustering independently per metric and concatenates the per-metric cluster labels into a phase vector identifying workload-level execution phases. The processor 210 may identify execution boundaries from the phase vector time series, map the execution boundaries to instruction-count positions using the retired-instruction counter, select a representative time point for each distinct execution phase, and generate the machine-readable control instructions specifying warm-up and detailed-simulation intervals in instruction counts for the architectural simulator. The architectural simulator simulates only the representative execution phases, which may result in achieving a potential simulation time reduction of approximately 6.8× to 194.8×, while maintaining reconstruction correlation above 84% for short benchmarks and above 99% for long-running server workloads, validated using normalized root mean square error, cross-correlation coefficient, dynamic time warping distance, and Kullback-Leibler divergence.

An example code for python implementation of phase detection algorithm as described herein may be as follows:

```
def detect_phases_single_metric(emon_data, metric, denoising_window=5,
          n_clusters_range=range(2, 10)):
  “““Detect phases based on a single metric using Kalman filtering and clustering.”””
  metric_agg = emon_data.per_sample_aggregate(metric, ‘sum’).df
  denoised = denoise_series(metric_agg, window=denoising_window)
  state_means, state_covariances = kalman_filter_1D(denoised.values)
  feature_vectors, feature_labels = calculate_features_from_kalman(state_means)
  ... # Additional error handling code omitted.
  n_clusters, kmeans_model, score =
      optimal_k_silhouette(feature_vectors,k_range=n_clusters_range)
  phase_labels = kmeans_model.labels_{—}
  label_samples = { }
  for i, label in enumerate(phase_labels):
    if label not in label_samples:
        label_samples[label] = [ ]
    label_samples[label].append(i)
  phase_ranges = { }
  for label, samples in label_samples.items( ):
    phase_ranges[label] = compress_ranges(samples)
  return phase_labels, phase_ranges, kmeans_model
```

An example of a phase trajectory reconstruction function has been provided as follows, given phase_labels and sampling data, full metric timeseries can be reconstructed. In this example we emulate sampling using full hardware data. Representative samples are selected based on phase_labels and sampled from the full timeseries. Next, the cumulative series is reconstructed with only the limited number of values and known sample ID→phase assignments.

```
def reconstruct_with_phase_weighting(emon_data, metric, phase_labels):
  ″″″Reconstruction using derivative-based interpolation between sampling points.”””
  per_sample = emon_data.per_sample_aggregate(metric, ‘sum’).df.values
  hw_cumulative = numpy.cumsum(per_sample)
  n_samples = len(hw_cumulative)
  # Find sampling points (phase transitions + first and last sample)
  representative_indices = [0] # Always include first sample
  for i in range(1, len(phase_labels)):
    if phase_labels[i] != phase_labels[i−1]:
      representative_indices.append(i)
  # Always include last sample as endpoint
  if representative_indices[−1] != n_samples − 1:
    representative_indices.append(n_samples − 1)
  representative_values_cumul = hw_cumulative[representative_indices]
  # Reconstruct using derivative between sampling points
  reconstructed = numpy.zeros(n_samples)
  for seg_idx in range(len(representative_indices) − 1):
    start_idx = representative_indices[seg_idx]
    end_idx = representative_indices[seg_idx + 1]
    start_value = hw_cumulative[start_idx]
    end_value = hw_cumulative[end_idx]
    # Calculate derivative (slope) for this segment
    n_steps = end_idx − start_idx
    derivative = (end_value − start_value) / n_steps
    # Apply derivative to all samples in segment
    for i in range(start_idx, end_idx):
      reconstructed[i] = start_value + derivative * (i − start_idx)
  # Set the last sample to exact value
  reconstructed[−1] = hw_cumulative[−1]
  return reconstructed, representative_indices, representative_values_cumul
```

In an example, the processor 210 is further configured to prepare the time-series hardware performance data by one or more of: i) summing hardware performance counter values across a plurality of processor cores to produce a per-time-point aggregate value; ii) computing a running sum of the hardware performance counter values over successive time points prior to applying the state estimation filter; or iii) applying a moving average filter to the time-series hardware performance data prior to applying the state estimation filter. These three preparatory operations address distinct signal quality issues in the raw counter data and may be applied individually or in combination, as represented by the input stage 301. The summing operation may perform spatial aggregation, such that the per-core counter values measured at each sampling instant are summed across the processor cores to yield a single aggregate value per time point, which results in collapsing the per-core dimension and removing inter-core variability. In an example, the summation is performed across all cores of the physical processor. In an alternative example, the summation may exclude idle cores, which can be cores whose counter values indicate no active workload execution during the sampling interval, so that the aggregate reflects only the active execution behavior of the software workload. The cumulative sum operation may perform temporal accumulation, such that each per-time-point aggregate value is added to a running total over the sequence of sampling instants, converting per-interval delta values into a monotonically increasing signal. Applying spatial aggregation followed by temporal accumulation produces a monotonically increasing per-platform aggregate time-series, which eliminates per-core variability and inter-sample jitter simultaneously prior to the state estimation filter.

In an example, the time-series hardware performance data is provided in a text-based format. In the format, each data line may begin with the name of the hardware performance counter metric, for example, INST_RETIRED.ANY_P, followed by a reference clock cycle count that serves as the timestamp for the reading, followed by per-core counter values for that metric at that sampling instant. The PMU of the physical processor may be programmed to read a selected group of hardware performance counter metrics periodically. Each group readout represents one sampling instant, and all metric values collected during that readout constitute one sample of the time-series hardware performance data. The number of hardware performance counter metrics in the selected group determines the vector length of each sample. Because the PMU can read multiple event groups in sequence within each nominal sampling period, each group readout varies in actual interval duration and in sample duration due to timing jitter. No two consecutive sampling intervals are guaranteed to be of equal duration. This timing jitter introduces variability in raw per-interval delta values that accumulates over successive samples. The cumulative sum operation converts these timing-sensitive per-interval delta values into monotonically increasing cumulative values, making the resulting time-series substantially more uniform in scale for subsequent processing by the state estimation filter.

In an example, the processor 210 prepares the time-series hardware performance data for a given hardware performance counter metric by applying the following sequence of operations. The processor 210 may first sum the per-core counter values for the metric at each sampling instant across all active processor cores to produce a per-time-point aggregate value. Second, the processor 210 may apply a moving average filter to the aggregate values to suppress high-frequency measurement noise. For example, the processor 210 may, for each time point via the moving average filter, compute the mean of the aggregate values within a window of consecutive time points centered at or ending at that time point. The window size of the moving average filter may range from 2 to 20 time points; in a preferred range, the window size is from 3 to 10 time points; in a specific example, the window size is 5 time points. Third, the processor 210 may supply the denoised aggregate values to the state estimation filter as the observation sequence. The moving average step may be applied before or after the cumulative sum, depending on whether noise suppression is desired on the raw per-interval values or on the cumulated signal. Applying spatial aggregation, temporal accumulation, and moving average smoothing collectively reduces jitter, inter-core variability, and high-frequency noise before the state estimation filter processes the data.

In an example, the state estimation filter includes a recursive filter that maintains a joint state comprising a filtered counter value and a trend estimate. The joint state may be updated at each successive time point using a dynamical model in which the filtered counter value at a next time point is predicted based on a current filtered counter value and a current trend estimate. It is to be noted that a simple low-pass filter produces a single smoothed output value at each time point, while the recursive filter with joint state produces both a filtered counter value and a trend estimate as co-equal components of the state vector, making the trend estimate directly available for downstream feature extraction without a separate differentiation step. The recursive filter may be implemented using a Kalman filter library, in which the filter is instantiated with transition matrix, observation matrix, and noise covariance parameters and applied to the observation sequence in a single call returning state vectors and state covariance matrices for all time points. In an alternative, the recursive filter may be implemented using custom matrix operations in which the transition matrix F=[[1, 1], [0, 1]] and observation matrix H=[[1, 0]] are applied explicitly at each time point to compute the predicted state vector, the innovation, the Kalman gain, and the updated state vector. Both implementations can produce numerically equivalent results for linear-Gaussian inputs.

In an example, the processor 210 initializes and applies the state estimation filter as follows. The processor 210 may compute an initial trend estimate as the mean of the first-order differences of the first five consecutive time points of the time-series hardware performance data. The processor 210 may set an initial state vector to the two-element vector comprising the first data value as the filtered counter value component and the initial trend estimate as the trend estimate component. The processor 210 may further set an observation noise variance is set to the variance of all data values in the complete time-series hardware performance data. The processor 210 may form a process noise covariance matrix as the product of the scalar process noise variance and the two-by-two identity matrix, where the process noise variance is set to 0.01 multiplied by the observation noise variance. An initial state covariance matrix is set to the two-by-two identity matrix. The processor 210 may then instantiate the state estimation filter with the transition matrix [[1, 1], [0, 1]], the observation matrix [[1, 0]], the initial state vector, the initial state covariance matrix, the scalar observation noise variance, and the process noise covariance matrix. The filter is then applied to the complete sequence of hardware performance counter observations, producing a state vector, comprising a filtered counter value and a trend estimate, and a state covariance matrix for each time point. The number of initial first-order differences used to estimate the initial trend may range from 2 to 20; in a preferred range, from 3 to 10; in a specific example, 5.

In an example, the observation noise variance and the process noise variance of the state estimation filter are derived from statistical properties of the time-series hardware performance data computed over the entire observed time-series. The observation noise variance may be set equal to the variance of all data values in the time-series hardware performance data, computed from the complete measurement sequence. The process noise variance may be set equal to a fixed fraction of the observation noise variance. The fraction may range from 0.001 to 0.1; in a preferred range, the fraction is from 0.005 to 0.05; in a specific example, the fraction is 0.01, setting the process noise variance equal to one percent of the observation noise variance. Setting the process noise variance substantially smaller than the observation noise variance causes the state estimation filter to weight the predictions of its dynamical model more heavily than individual observations, producing smooth state estimates that are insensitive to individual noisy observations while remaining responsive to sustained changes in the trend of the hardware performance counter metric. In an alternative, the fraction may be estimated by maximum-likelihood optimization on a training subset of the time-series hardware performance data, selecting the fraction that maximizes the likelihood of the observed sequence under the state-space model. Computing the noise parameters from the full time-series requires that the complete measurement sequence be available before the state estimation filter is applied, which is the operating condition of the offline analysis mode.

In an example, the initial state vector of the state estimation filter comprises, as the filtered counter value component, the first data value in the time-series hardware performance data and, as the trend estimate component, the mean of the first-order differences computed from the first five consecutive data values. Using the first data value as the initial filtered counter value anchors the filter at the correct signal level from the first observation, avoiding a transient during which the filter must locate the signal level from an incorrect starting point. Using the mean of the first several first-order differences as the initial trend estimate provides a robust starting slope that is less sensitive to individual noisy observations than using a single first-order difference. The initial state covariance matrix may be set to the two-by-two identity matrix, expressing equal and maximum initial uncertainty in both components of the joint state. This choice causes the state estimation filter to weight the first few observations heavily, allowing the state estimates to converge rapidly toward data-consistent values. The convergence behavior can be reflected in the state covariance matrix, which contracts from the identity initialization toward smaller values as observations accumulate during the initial time points.

In an example, the state estimation filter is configured to estimate its observation noise variance and process noise variance from the time-series hardware performance data observed up to each current time point, without requiring access to future time points. At each time point t, the observation noise variance may be estimated as the variance of all data values observed from the start of the time-series up to and including time point t, using an expanding window that grows by one element at each successive time point. The process noise variance may be set to a fixed fraction of the current observation noise variance estimate, using the same fraction as the offline configuration described above. In an alternative, the observation noise variance may be estimated from a fixed-size sliding window comprising the most recent W time points rather than from an expanding window, enabling the noise estimate to adapt to slowly varying noise characteristics of the hardware performance counter metric; the window size W may range from 2 to 20, for example from 3 to 10, for example 5. The online noise parameter estimates may require a convergence period during the initial time points of the time-series, during which the variance is computed from few observations and may underestimate the long-run variance. After a sufficient number of observations accumulate, the estimates stabilize toward the values that would be obtained by the offline computation. Online noise parameter estimation enables the state estimation filter to operate in a streaming mode, processing each new hardware performance counter observation as it is received from the physical processor, which is the operating condition required for hardware implementations of the phase detection pipeline 300.

In an example, the processor 210 assigns the sequential time points to distinct execution phases by computing, for each time point, a multi-dimensional feature vector derived from at least the state vector, and applying a clustering algorithm to the multi-dimensional feature vectors to determine a cluster label for each time point, each distinct cluster label corresponding to a distinct execution phase. The processor 210 may derive the multi-dimensional feature vector from the filtered counter value component of the state vector alone, or from both the filtered counter value component and the trend estimate component. The multi-dimensional feature vector may additionally incorporate features derived from differences between state vectors at successive time points or from local statistics of the filtered counter values. Conditioning phase assignment on a multi-dimensional feature vector that includes the trend estimate component distinguishes execution phases that have similar counter levels but different dynamics. For example, an initialization phase during which the hardware performance counter metric is rising rapidly and a steady-state phase during which the hardware performance counter metric is approximately constant, even when their instantaneous counter values overlap. When the state estimation filter maintains a joint state comprising a filtered counter value and a trend estimate, the trend estimate is a first-class output of the joint state at every time point, directly available as a feature dimension without an additional differentiation step applied to the sequence of filtered counter values.

In an example, the processor 210 computes the multi-dimensional feature vector for each time point t as follows. The first element of the feature vector is set to the filtered counter value component of the state vector at time point t. The second element is set to the trend estimate component of the state vector at time point t. The third element is set to the difference between the trend estimate component of the state vector at time point t and the trend estimate component of the state vector at time point t-1. The fourth element is set to the Euclidean norm of the two-element vector formed by subtracting the state vector at time point t-1 from the state vector at time point t, that is, the norm of the vector comprising the change in filtered counter value and the change in trend estimate between consecutive time points. The fifth element is set to the variance of the filtered counter value components of the state vectors for the time points from max (0, t-w) to t inclusive, where w is the sliding window size. After computing the feature vector for every time point, the processor 210 may apply z-score normalization to the complete set of feature vectors dimension-by-dimension, which may include, for each of the five dimensions, the processor 210 subtracting the mean of that dimension's values across all time points and dividing by the standard deviation of that dimension's values across all time points. The processor 210 may supply the normalized multi-dimensional feature vectors to the clustering algorithm.

In an example, the multi-dimensional feature vector for each time point comprises all five of the above-mentioned: the filtered counter value, the trend estimate, the difference between trend estimates at successive time points, the Euclidean norm of the state vector difference between successive time points, and the variance of filtered counter values within the sliding window. Using all five features simultaneously can provide rich behavioral representation of the time-series hardware performance data at each time point. Each of the five features captures a distinct aspect of the counter time-series behavior, and the features are non-redundant in the sense that each dimension contributes information that is not replicated by any combination of the remaining dimensions. Different features exhibit non-equivalent time-varying characteristics across the execution of a software workload, meaning that the use of a subset of features, for example, using only the filtered counter value and the trend estimate, results in a coarser partitioning than using all five. In applications where computational or hardware resources for feature extraction are constrained, any two or more of the five features may be used the reduction in feature dimensionality reduces both computation and storage requirements at the cost of reduced phase-discrimination capability.

In an example, the processor 210 may normalize the multi-dimensional feature vectors dimension-by-dimension by subtracting a mean value and dividing by a standard deviation. The processor 210 may compute each of them across a window of time points, prior to applying the clustering algorithm. The processor 210 may apply the normalization after the multi-dimensional feature vectors have been computed for all time points and before the feature vectors are supplied to the clustering algorithm, so that the normalized feature vectors are the sole input to all cluster distance computations. The processor 210 may compute the mean and standard deviation across all time points of the time-series hardware performance data in an offline computation, which may involve fitting the normalization statistics to the complete feature dataset before clustering begins, which is suitable when the complete time-series is available before clustering. The mean and standard deviation may alternatively be computed from a sliding window of recent time points, enabling normalization to adapt to gradual statistical shifts in the hardware performance counter metric over the course of a long-running workload. In a specific example, the processor 210 may compute the normalization statistics across all time points at once, yielding zero-mean, unit-variance feature dimensions, corresponding to z-score normalization. Normalization ensures that all feature dimensions contribute equally to the distance computations performed by the clustering algorithm regardless of the absolute magnitude of each feature. Without normalization, feature dimensions with large absolute values, such as the filtered counter value of a hardware performance counter metric that accumulates to large cumulative counts, would dominate cluster distance computations, diminishing the influence of features with smaller magnitudes, such as the trend difference, and reducing the discriminative power of the multi-dimensional feature representation.

In an example, the processor 210 determines the number of clusters for the clustering algorithm by applying the clustering algorithm for each candidate number of clusters within a predefined range, computing a score for each candidate number based on intra-cluster and inter-cluster distances of the multi-dimensional feature vectors, and selecting the candidate number of clusters yielding the highest score. The score here may include a silhouette score or another internal clustering validity index that quantifies cluster cohesion and separation without distributional assumptions. The predefined range of candidate cluster counts spans from a minimum of 2 to a configurable maximum. The maximum may be up to 50, for example up to 15, for example 9. For each candidate cluster count K, the processor 210 may apply the clustering algorithm to the normalized multi-dimensional feature vectors, assign a cluster label to each time point, and compute the silhouette score of the resulting assignment. In a degenerate case in which the clustering algorithm assigns all time points to a single cluster label, the processor 210 may set the silhouette score to a sentinel value, for example −0.99, to prevent selection of that degenerate candidate. The candidate K yielding the highest silhouette score across all evaluated candidates is selected as the number of clusters. The processor 210 may evaluate candidates by linear search over the full predefined range. The processor 210 may alternatively employ a bisection-based search that exploits the approximate smoothness of the silhouette score as a function of K. The upper bound of the predefined range may additionally be established by applying principal component analysis to the feature dataset and using the number of principal components needed to explain a target fraction of variance as an upper bound on the number of distinguishable phases.

In an example, the processor 210 selects the optimal cluster count by the following procedure. The processor 210 initializes a best silhouette score to −1 and the current optimal cluster count to the lowest candidate value in the predefined range. The processor 210 iterates over each candidate cluster count K within the predefined range. For each K, the processor 210 fits a k-means model to the normalized multi-dimensional feature vectors. If the resulting cluster label assignment produces more than one distinct cluster label among the time points, the processor 210 computes the silhouette score of that assignment. If all time points receive the same cluster label, the processor 210 assigns the sentinel score −0.99. If the computed score exceeds the current best silhouette score, the processor 210 updates the best silhouette score to the computed score, the optimal cluster count to K, and the best clustering model to the current model. After iterating over the full predefined range, the processor 210 returns the optimal cluster count, the best clustering model, and the best silhouette score achieved. The best clustering model is subsequently applied to the normalized multi-dimensional feature vectors of all time points to assign a cluster label to each time point. These cluster labels constitute the per-time-point, per-metric phase assignments used for phase vector construction, execution boundary identification, and machine-readable control instruction generation, as described above.

The time-series hardware performance data may include a plurality of hardware performance counter metrics and the processor 210 may apply the state estimation filter independently to each hardware performance counter metric, assign a cluster label to each time point for each metric, and assign each time point to a distinct execution phase based on a concatenation of the cluster labels across all hardware performance counter metrics at that time point. For a set of M hardware performance counter metrics, the processor 210 may apply the state estimation filter M times independently, once per metric, producing M separate state vector time-series. The clustering algorithm is then applied independently to the multi-dimensional feature vectors derived from each state vector time-series, yielding M per-metric cluster label sequences. At each time point, the M cluster labels are concatenated to form a phase vector of length M. All time points sharing an identical phase vector are assigned the same phase identifier and belong to the same distinct execution phase, as represented within the clustering stage 304 and the phase labels block 315 of the phase processing stage 305. The phase identifier is a compact discrete label assigned to each unique phase vector value, enabling efficient storage and manipulation of the phase assignments. This per-metric-independent processing followed by label concatenation captures cross-metric behavioral correlations. An execution phase that is identical in one hardware performance counter metric but differs in another yields a different phase vector and may therefore be assigned a distinct phase identifier. In an alternative, joint multi-variate state estimation may be applied to a concatenated state vector spanning all M metrics simultaneously, followed by a single clustering step on the resulting joint multi-dimensional feature space.

In an example, the mapping between time points and phase identifiers may be understood through the following illustration of a sample-to-phase-vector assignment. A first time point has cluster label 1 for the INST_RETIRED.ANY_P metric, cluster label 0 for the LID.REPLACEMENT metric, and cluster label 2 for the CPU_CLK_UNHALTED.THREAD_P metric, yielding phase vector (1, 0, 2, . . . ) and phase identifier 0. A second time point with identical cluster labels across all metrics yields the same phase vector and is therefore assigned phase identifier 0, belonging to the same distinct execution phase as the first time point. A third time point with cluster label 1 for INST_RETIRED.ANY_P, cluster label 1 for LID.REPLACEMENT, and cluster label 2 for CPU_CLK_UNHALTED.THREAD_P yields phase vector (1, 1, 2, . . . ), which differs from the preceding phase vector; this time point is accordingly assigned a distinct phase identifier 1. Time points sharing an identical phase vector belong to the same execution phase and exhibit the same qualitative hardware performance counter characteristics as captured by the phase vector. A property of this phase-vector construction is that measuring the hardware performance counter characteristics of one time point belonging to a given phase identifier is representative of all time points sharing that identifier, since the phase vector ensures that all such time points have been classified identically by the state estimation and clustering procedure across every monitored metric.

In an example, the processor 210 applies the following procedure for each hardware performance counter metric independently. The per-core counter values for the metric at each sampling instant are summed across the active processor cores to produce a per-time-point aggregate time-series. A moving average filter with a window of 5 time points is applied to the aggregate time-series to suppress high-frequency noise. The state estimation filter is applied to the denoised aggregate time-series, producing a state vector comprising a filtered counter value and a trend estimate at each time point. A five-dimensional feature vector is computed from the state vectors as described above, and the silhouette-optimized clustering procedure selects the optimal cluster count and assigns a cluster label to each time point. The processor 210 records, for each distinct cluster label, the set of time point indices to which that label is assigned, and compresses this information into phase ranges: contiguous spans of time points sharing the same cluster label are stored as start-sample-index and end-sample-index pairs. After this procedure has been applied independently to each hardware performance counter metric, the per-metric cluster label sequences are concatenated time-point-by-time-point to construct the phase vector sequence, from which phase identifiers are derived and execution boundaries between distinct execution phases are identified by the phase boundary detection block 316.

In an example, the execution boundaries are expressed as instruction counts derived from a cumulative value of a retired-instruction counter of the physical processor. Here, each execution boundary may indicate a start offset and a duration in terms of instruction counts. Expressing phase boundaries in instruction-count coordinates, rather than wall-clock time or sample-index coordinates, provides a position metric that is invariant to processor clock frequency, dynamic voltage and frequency scaling, and operating system scheduling variability. The retired-instruction counter is a monotonically increasing hardware performance counter metric that increments for each instruction committed by the physical processor. The cumulative value of the retired instruction counter can be at any time point equal the total number of instructions committed from the start of workload execution up to that point. The start offset of each execution boundary may be the cumulative instruction count at the beginning of the representative sample for the corresponding execution phase, and the duration of each execution boundary may be the difference in cumulative instruction count from the beginning to the end of the representative sample interval, as implemented by the instruction count mapping block 317 of the phase processing stage 305. In an example, the retired-instruction counter used for instruction-count derivation is the INST_RETIRED.ANY_P performance monitoring event. In an alternative, any retired-instruction counter available on the target processor architecture that provides a monotonically increasing count of committed instructions may be used, enabling the approach to be applied across different processor families without modification to the phase detection pipeline 300.

In an example, the processor 210 stores the phase information and the corresponding instruction-count boundaries in a structured data format. For a client-server workload, the structured data comprises a first section containing, for each hardware performance counter metric, the sequence of per-time-point cluster labels assigned to the client core group, and a second section containing the corresponding sequence for the server core group. A phase ranges section may map each phase vector string to a list of time-point range pairs, each pair specifying the start and end sample indices of a contiguous span of time points sharing that phase vector. A phase offsets section may map each phase vector string to its instruction-count representation: for a phase vector occupying time-point ranges [0, 45] and [120, 180], the corresponding entry records those time-point ranges, the instruction count at the start of the first representative sample, for example, 0 retired instructions, and the instruction count at the end of the last representative sample, for example, 4,500,000,000 retired instructions. A second phase vector occupying time-point range [46, 119] may have a corresponding instruction count start of 4,500,000,000 and end of 7,300,000,000. This structured format may be stored as a persistent file that enables post-simulation reconstruction of the full time-series once simulation data becomes available, and may serve as the input to the simulator command generator block 318 for producing the machine-readable control instructions.

In an example, the processor 210 may select a single representative time point for each distinct execution phase and generate the one or more machine-readable control instructions to indicate execution boundaries corresponding to the representative time points. The representative time points may be selected such that the latest representative time point in temporal order occurs as early as practicable in the time-series hardware performance data. For each distinct phase identifier, the processor 210 may select the time point with the smallest sample index among all time points assigned to that phase identifier, which is the earliest-occurring time point belonging to that phase in the workload execution trace, as the representative time point for that phase. Selecting the earliest representative per phase ensures that the time point corresponding to the last simulated phase occurs as early as possible in the execution trace, enabling the architectural simulator to terminate the simulation run before the end of the full workload execution. This early termination can be the primary mechanism by which simulation time is reduced for long-running workloads that continue without terminating, such as continuously operating server applications. For example, the architectural simulator simulates only the representative phases identified in the early portion of the execution trace and then stops, avoiding the need to simulate the remaining workload execution. In an alternative, the representative time point for each phase may be selected as the time point whose normalized multi-dimensional feature vector lies closest to the centroid of that phase's cluster, providing the most statistically central sample of the phase rather than the earliest.

In an example, the one or more machine-readable control instructions indicate, for each distinct execution phase, a warm-up interval followed by a detailed-simulation interval. A warm-up interval may refer to a number of instructions that the architectural simulator executes at reduced fidelity to initialize microarchitectural state, including cache contents and branch-predictor state, before a detailed-simulation interval commences. The warm-up interval may represent a number of instructions for execution at reduced simulation fidelity before the detailed-simulation interval commences. The warm-up interval and the detailed-simulation interval can each be expressed as instruction counts in the machine-readable control instructions. During the warm-up interval, the architectural simulator can execute the corresponding instructions at reduced simulation fidelity, for example, in a functional or reduced-pipeline mode, to initialize the microarchitectural state of the simulated processor model, including cache contents, branch-predictor training state, and prefetcher state, to a condition that approximates what would exist at that point in native execution of the software workload. During the detailed-simulation interval, the architectural simulator may execute the corresponding instructions at full cycle-accurate fidelity, collecting timing and performance metrics that constitute the simulation output for that execution phase. The warm-up mode may be preferred over a fast-forward mode for initializing microarchitectural state because the warm-up mode achieves improved fidelity of microarchitectural state initialization at negligible additional simulation time overhead relative to fast-forward mode, which executes instructions functionally without any pipeline model activity. The machine-readable control instructions may specify distinct warm-up and detailed-simulation instruction counts for each representative execution phase, enabling the architectural simulator to allocate different warm-up durations to phases with different microarchitectural complexity.

In an example, the machine-readable control instructions for the architectural simulator take the form of a region-of-interest control sequence structured as: “control:start:icount:S, warmup:icount:W1, detailed:icount:D1, warmup:icount:W2, detailed:icount:D2, . . . , stop”, where S is the start instruction count for the simulation run, W1 and D1 are the warm-up and detailed-simulation instruction counts for the first representative phase, and each subsequent warmup-detailed pair corresponds to the next representative phase in temporal order. The start instruction count is typically 0 for simulations beginning from the start of workload execution. For the FFT benchmark in a specific example, the first representative phase warm-up instruction count is approximately 91,905,002 instructions and the first representative phase detailed-simulation instruction count is approximately 183,512,091 instructions. The control sequence may be passed as an argument to the architectural simulator at invocation, alongside configuration arguments specifying the target processor model, disabled core identifiers, and the output directory. The instruction count values in the control sequence are computed from the cumulated retired-instruction counter values of the time-series hardware performance data at the boundaries of the representative sample intervals, using the phase detection assignments produced by the phase detection pipeline 300. The specific command-line format illustrated is that of an example architectural simulator supporting region-of-interest specification. The control instruction structure is adaptable to any simulator supporting warm-up and detailed-simulation interval specification in instruction counts.

In an example, the device 200 further comprises the architectural simulator configured to receive the one or more machine-readable control instructions from the processor 210 and to simulate the software workload by switching between execution modes according to the execution boundaries indicated by the one or more machine-readable control instructions. The architectural simulator may be co-located with the processor 210 on the same computing system, receiving the machine-readable control instructions via an internal bus, a shared file system, or an application programming interface call. In an example, the architectural simulator executes as a software process on the same computing system as the phase detection pipeline 300, reads the machine-readable control instructions from a Javascript Object Notation file produced by the processor 210 upon completion of phase detection, and proceeds to execute the reduced simulation without additional operator intervention. In an alternative, the architectural simulator may execute on a remote computing system connected to the device 200 via the communication interface 230 and the network 190, receiving the machine-readable control instructions via a network file transfer after the processor 210 completes phase detection. The integration of the architectural simulator within the device 200 forms a closed-loop apparatus in which hardware performance counter measurement, phase detection, and cycle-accurate simulation of the representative execution phases are performed as a continuous automated pipeline.

As mentioned, the processor 210 may be the same processor as the physical processor. In this configuration, the processor 210 of the device 200 both executes the software workload natively, generate the time-series hardware performance data through its own PMU, and perform the phase detection analysis on that data. The same-processor configuration may be realized by executing the software-based phase detection pipeline 300 on idle processor cores of the physical processor, or on a dedicated co-processor integrated on the same processor die, while the software workload executes on the remaining cores. When the processor 210 is the same as the physical processor and additionally comprises dedicated digital logic for phase detection, the phase detection pipeline 300 executes entirely within the processor die, using the PMU counter streams as input without external data transfer. This configuration can enable real-time phase detection and control. For example, upon detecting a transition between distinct execution phases via the dedicated digital logic, the processor may issue a phase-detection interrupt that triggers control decisions, including dynamic voltage and frequency scaling, cache partitioning, prefetcher tuning, and power management, without incurring the latency of transmitting performance counter data to an external system. The same-processor configuration is applicable to both the software-based phase detection pipeline and the hardware implementation. The physical processor may utilize CPUID feature flags, for example via a dedicated CPUID leaf, to indicate hardware phase detection capabilities, version information, and feature bits to executing software. Furthermore, the phase-tagged records output by the dedicated digital logic may specifically comprise Phase-Tagged Processor Event-Based Sampling (PEBS) records that include phase identifier annotations alongside traditional performance counter values. Additionally, the computing system may include firmware or Basic Input/Output System (BIOS) configuration interfaces providing setup options for the dedicated digital logic, which may include configurable phase detection sensitivity thresholds, maximum cluster counts, and phase change interrupt enablement.

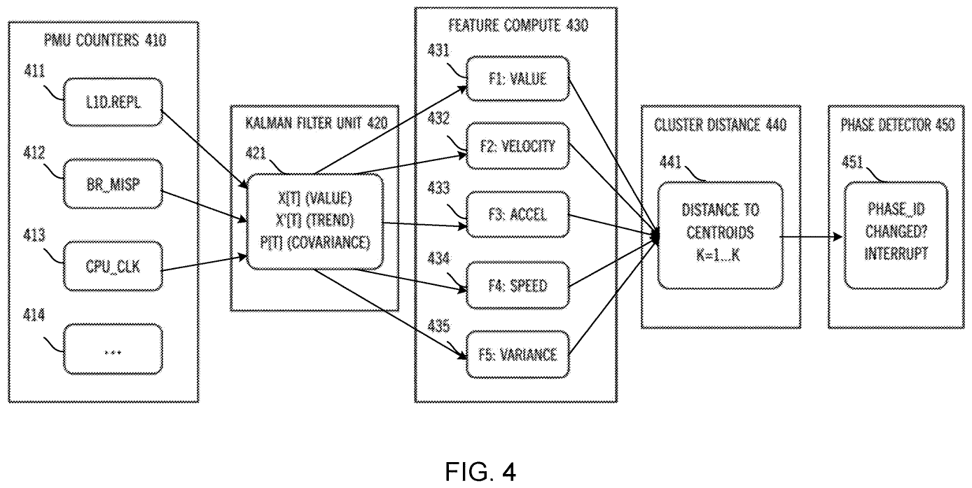

FIG. 4 shows an example illustration of a hardware implementation pipeline. The hardware implementation pipeline for phase detection receives input from a PMU counters block 410 comprising individual hardware performance counter streams, including an LID.REPL counter 411, a BR_MISP counter 412, a CPU_CLK counter 413, and additional counters 414 representing other monitored hardware performance counter metrics. Each counter stream from the PMU counters block 410 may be directed to a Kalman Filter Unit 420. The Kalman Filter Unit 420 maintains a state block 421 comprising the current filtered counter value X[T], the current trend estimate X′[T], and the current state covariance P[T], implementing the constant-velocity dynamical model in hardware. The Kalman Filter Unit 420 outputs the updated state values to a Feature Compute unit 430. The Feature Compute unit 430 comprises five computational sub-units operating in parallel: an F1 value sub-unit 431 that outputs the filtered counter value X[T]; an F2 velocity sub-unit 432 that outputs the trend estimate X′[T]; an F3 acceleration sub-unit 433 that computes the difference between the current trend estimate X′[T] and the preceding trend estimate X′[T-1]; an F4 speed sub-unit 434 that computes the Euclidean norm of the difference between the current state vector and the preceding state vector; and an F5 variance sub-unit 435 that computes the variance of the filtered counter values within a rolling buffer of the most recent time points. The five feature outputs of the Feature Compute unit 430 are directed to a Cluster Distance unit 440. The Cluster Distance unit 440 contains a distance-to-centroids block 441 that computes the Euclidean distance from the current five-dimensional feature vector to each of the K stored cluster centroids. The output of the Cluster Distance unit 440, e.g., the index of the nearest centroid, is passed to a Phase Detector unit 450, which contains a phase identifier block 451 that determines whether the current phase identifier differs from the phase identifier at the immediately preceding time point, sets the phase-change status indicator if a change is detected, and issues a phase-detection interrupt to notify the processor of the phase transition. As used herein, the term “phase-change status indicator” refers to a signal or flag set by the dedicated digital logic upon detecting that the execution phase assigned to the current time point differs from the execution phase assigned to the preceding time point.

The hardware implementation pipeline illustrated in FIG. 4 is designed to achieve one-sample throughput, processing one new time point from each PMU counter stream per sampling interval. The pipeline latency may be determined primarily by the Cluster Distance unit 440, which computes distances to K stored centroids and may use iterative refinement methods for the distance computations; for a small number of features and centroids, this latency is not prohibitive. A minimum PMU sampling interval of approximately 100 milliseconds has been established empirically as an initial upper bound for the maximum pipeline latency in software-based measurement configurations. The sampling interval may range broadly from approximately 1 millisecond to approximately 10 seconds; in a preferred range, the sampling interval is from approximately 10 milliseconds to approximately 1 second; in a specific example, the sampling interval is approximately 100 milliseconds. At sampling intervals shorter than approximately 100 milliseconds, increasing measurement noise has been observed in software-based measurement setups, likely due to the metrology overhead of software-based PMU reading utilities; whether a hardware-only implementation can reduce the minimum viable sampling interval without incurring increased measurement noise is an open question for further investigation. The sampling latency determines the control responsiveness of applications that act on phase-detection interrupts: the interval between the onset of a phase transition and the corresponding control action is bounded by the sampling interval, and this control lag must be accounted for in the design of real-time control systems that use phase-change events from the Phase Detector unit 450.

In various aspects described herein, the time-series hardware performance data may include first hardware performance counter data collected from a first set of processor cores assigned to a first process and second hardware performance counter data collected from a second set of processor cores assigned to a second process. In this example, the processor 210 may temporally align the first and second hardware performance counter data by resampling to a common time base prior to applying the state estimation filter, and to apply the state estimation filter independently to the aligned first and second hardware performance counter data and to assign each time point to a distinct execution phase based on state vectors derived from both the first and second hardware performance counter data. The first process may be a client application and the second process may be a server application of a client-server workload, with each process group assigned to a dedicated set of processor cores by affinity control so that the performance counter readings of the two groups are separable by core identifier. Temporal alignment addresses the case in which the first and second hardware performance counter data are collected with nominally equal sampling intervals but potentially different reference timestamps. Resampling maps both sequences to a common time base so that corresponding time points from the two core groups represent the same instant in workload execution. Applying the state estimation filter independently to the aligned first and second data and concatenating the resulting per-metric cluster labels for each core group into a unified phase vector effectively doubles the phase vector length relative to a single-process workload.

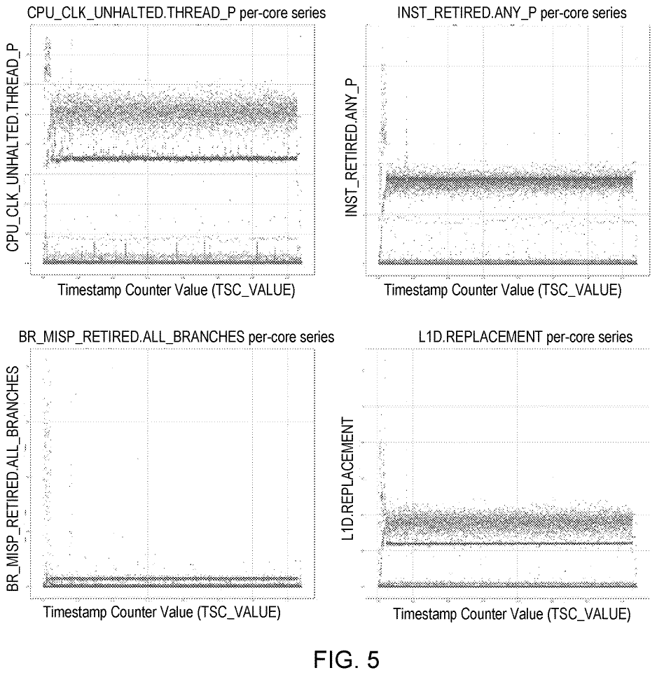

FIG. 5 illustrates per-core hardware performance counter readings for a client-server MongoDB workload measured during an example run of approximately 98 seconds on a single platform. The four sub-plots of FIG. 5 display, respectively, the CPU_CLK_UNHALTED.THREAD_P, INST_RETIRED.ANY_P, BR_MISP_RETIRED.ALL_BRANCHES, and LID.REPLACEMENT metrics. In each sub-plot, each color represents the time-varying counter readings of a single processor core. Three classes of cores are visible: client cores, server cores, and idle cores; the idle cores are filtered out and excluded from the per-core aggregation used for phase detection. The readings exhibit three discernible temporal regions: a dynamic initialization phase of approximately 10 seconds, a stabilization phase from approximately 10 to 30 seconds, and a steady-state operational phase from approximately 30 seconds onward. The mean counter values and transition dynamics differ visibly between the client and server core groups, indicating that the two process groups occupy distinct execution phases at certain time points and that sub-phases exist within the initialization region. A change in hardware performance counter characteristics after approximately 30 seconds may relate to power-management behavior of the physical processor. For phase detection, the client and server hardware performance counter metrics are treated as separate entries in the phase vector, enabling the phase detection pipeline 300 to distinguish phases that differ between client and server behavior.

In an example, the client-server measurement uses a single platform hosting both the client and server applications simultaneously, with affinity control configured so that the client process group runs on a first socket and the server process group runs on a second socket. A single collection of time-series hardware performance data may be performed across the entire platform, and the collected data may subsequently be partitioned by core assignment to produce separate first hardware performance counter data for the client core group and second hardware performance counter data for the server core group. Per-core counter values are aggregated and accumulated separately for each core group, and the state estimation filter, feature extraction, and clustering are applied independently to each metric for each core group. Treating the client and server metrics as separate time-series can affect only the number of time-series processed and the length of the phase vector. This approach generalizes to two-platform configurations in which the client and server applications run on separate physical platforms with independent time-series hardware performance data collection: in such configurations, resampling to a common time base is applied before the state estimation filter to ensure that corresponding time points from the two platforms represent the same point in workload execution.

The processor 210 may reconstruct an estimated time-series of a hardware performance counter metric by, for each execution phase, linearly interpolating between sampled counter values at the boundaries of that execution phase across all time points within that execution phase, and to evaluate reconstruction accuracy by computing at least one of a normalized root mean square error, a cross-correlation coefficient, a dynamic time warping distance, or a Kullback-Leibler divergence between the reconstructed estimated time-series and the time-series hardware performance data. The reconstruction procedure can emulate the time-series that would be produced by simulating only the representative execution phases and interpolating the resulting counter values across the full hardware sampling domain, enabling the accuracy of the phase-based sampling strategy to be evaluated against the complete hardware-measured time-series without requiring the full simulation to be run. The normalized root mean square error quantifies the magnitude of reconstruction error relative to the scale of the hardware-measured time-series. The cross-correlation coefficient quantifies agreement in the shape of the reconstructed and hardware-measured time-series. The dynamic time warping distance quantifies shape similarity while allowing for local temporal misalignment. The Kullback-Leibler divergence quantifies the difference in the statistical distributions of the two time-series values. In an alternative to linear interpolation, piecewise-constant interpolation may be applied, assigning the value of each representative sample to all time points within the corresponding execution phase.

In an example, the processor 210 reconstructs the estimated time-series as follows. The per-core counter values for the hardware performance counter metric are aggregated by summing across all active cores, and the cumulative sum of the aggregated values is computed over time to produce a monotonically increasing cumulative time-series. A set of representative sample indices is identified: the set always includes sample index 0 as the first representative, every sample index at which the phase label changes value relative to the immediately preceding sample, and the final sample index. The cumulative hardware-measured values at the representative sample indices are recorded as the representative cumulative values. The reconstructed time-series is computed segment by segment between consecutive representative sample indices: for each segment defined by a start representative index and an end representative index, a linear slope is computed as the difference in cumulative value between the end and start representative indices divided by the number of samples in the segment. The reconstructed cumulative value at each sample within the segment is set to the cumulative value at the start representative index plus the slope multiplied by the offset from the start index to that sample. The final sample of the reconstructed time-series is set to the exact hardware-measured cumulative value at the last sample index. The processor 210 returns the reconstructed time-series, the representative sample indices, and the representative cumulative values, which serve as inputs to the accuracy evaluation metrics and to the post-simulation reconstruction once simulation data is available.

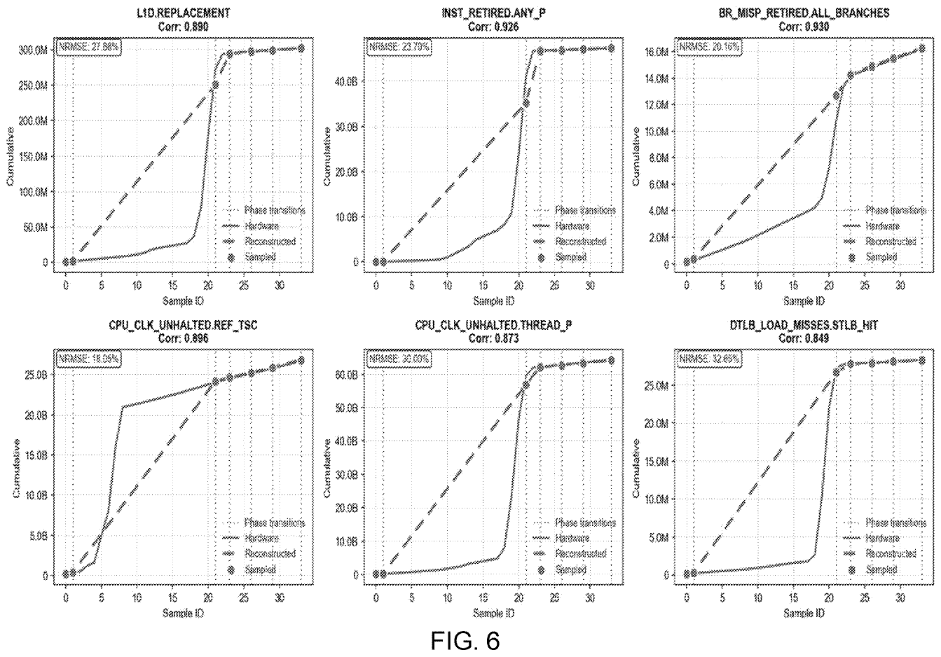

FIG. 6 illustrates a graph representation of an example benchmark involving phase-based reconstruction accuracy. It shows results for FFT hardware reconstruction. As illustrated in FIG. 6, the phase detection pipeline 300 identifies 5 distinct execution phases across 34 collected samples for an FFT benchmark executed on a 112-core platform, achieving a mean reconstruction correlation of 0.894 across all monitored hardware performance counter metrics. FIG. 6 displays six sub-plots corresponding to the LID.REPLACEMENT, INST_RETIRED.ANY_P, BR_MISP_RETIRED.ALL_BRANCHES, CPU_CLK_UNHALTED.REF_TSC, CPU_CLK_UNHALTED.THREAD_P, and DTLB_LOAD_MISSES.STLB_HIT metrics. In each sub-plot, the continuous line represents the hardware-measured cumulative time-series, the marked points represent the representative samples selected by the phase detection pipeline 300, and the dotted line represents the reconstructed estimated time-series. The x-axis corresponds to the original samples collected using EMON on an SPR (a server-class processor) platform (continuous blue line). The phase detection algorithm ingests the hardware data and selects the sampling points (red dots). The reconstruction algorithm resamples the phase-detected samples to the original hardware sampling domain (dotted line). Each series is compared using NRMSE and statistical correlation. Individual metric correlation values range from 0.849 to 0.930 and normalized root mean square error values range from 18.05% to 32.65%. The reconstruction error arises primarily from under-sampling between consecutive representative samples and from process-startup noise in the approximately 3-second FFT run.

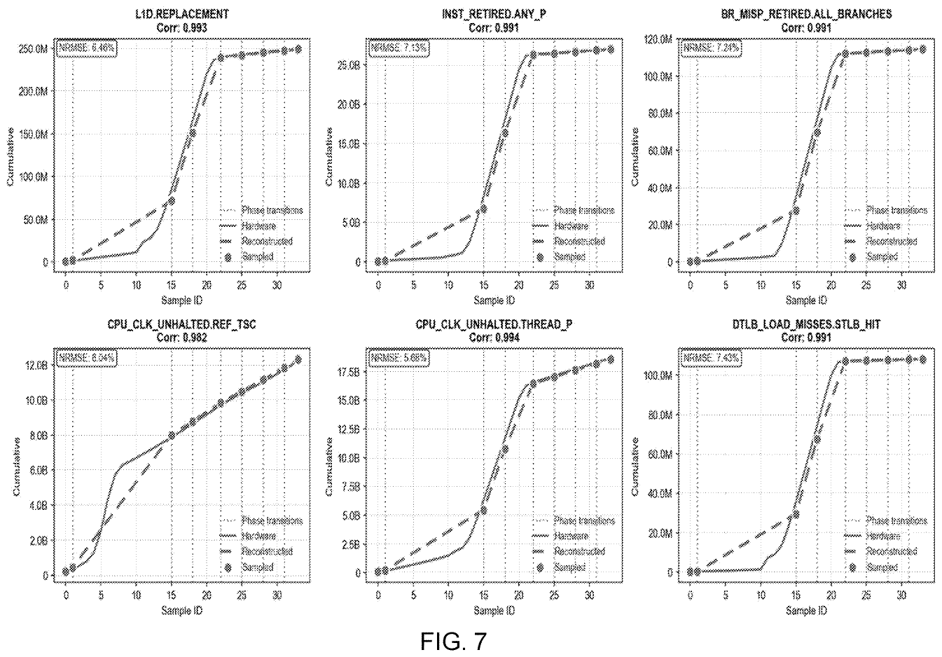

FIG. 7 illustrates a graph representation of another example benchmark involving phase-based reconstruction accuracy. It shows results for FFMPEG hardware reconstruction. It is to be noted that while the figure reflects hardware reconstruction accuracy, simulation-versus-hardware correlation has not been confirmed for FFMPEG example. As illustrated in FIG. 7, the phase detection pipeline 300 identifies 6 distinct execution phases across 34 collected samples for an FFMPEG benchmark executed on an 8-core platform, achieving a mean reconstruction correlation of 0.990. The x-axis corresponds to the original samples collected using EMON on an SPR platform (continuous blue line). The phase detection algorithm ingests the hardware data and selects the sampling points (red dots). The reconstruction algorithm resamples the phase-detected samples to the original hardware sampling domain (dotted line). Each series is compared using NRMSE and statistical correlation. Individual metric normalized root mean square error values range from 5.68% to 7.43% and individual correlation values range from 0.982 to 0.994, reflecting the higher regularity of the input/output-bound FFMPEG workload.

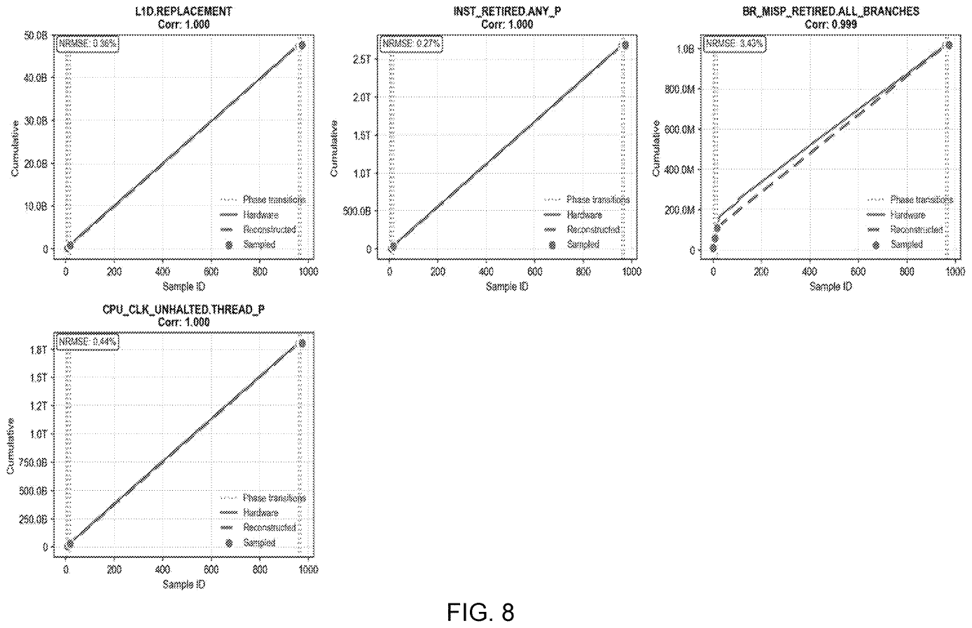

FIG. 8 illustrates a graph representation of a further example benchmark involving phase-based reconstruction accuracy. It shows results for a client-server MongoDB hardware reconstruction. It is to be noted that while the figure reflects hardware reconstruction accuracy, simulation-versus-hardware correlation has not been confirmed for MongoDB example. As illustrated in FIG. 8, the phase detection pipeline 300 identifies 2 distinct execution phases across 974 collected samples for a client-server MongoDB benchmark executed on a 16-core platform comprising 8 server cores and 8 client cores during a run of approximately 98 seconds, yielding a potential simulation speedup of 194.8×, which corresponds to simulating 5 representative samples from 974 total. The x-axis corresponds to the original samples collected using EMON on an SPR platform (continuous blue line). The phase detection algorithm ingests the hardware data and selects the sampling points (red dots). The reconstruction algorithm resamples the phase-detected samples to the original hardware sampling domain (dotted line). Each series is compared using NRMSE and statistical correlation. FIG. 8 displays four sub-plots for the LID.REPLACEMENT, INST_RETIRED.ANY_P, BR_MISP_RETIRED.ALL_BRANCHES, and CPU_CLK_UNHALTED.THREAD_P metrics; a smaller number of metrics is shown than for the FFT and FFMPEG benchmarks, reflecting the early stage of measurement development, and results are expected to be qualitatively consistent for additional metrics. Reconstruction correlation values exceed 0.999 and normalized root mean square error values are below 3.43% across all displayed metrics. The majority of the reconstruction error accumulates during the early stage of workload execution, where process startup and application initialization effects are most pronounced; additional tuning of the sampling procedure to compensate for these transitory effects is expected to improve the results without additional simulation time. The reconstruction accuracy figures for all three benchmarks represent hardware-based reconstruction accuracy, in which the reconstructed estimated time-series is compared to the hardware-measured time-series; simulation-versus-hardware accuracy has been confirmed for the FFT benchmark. At a simulation slowdown of 100,000×, full cycle-accurate simulation of the approximately 97.4-second MongoDB workload would require approximately 113 days of continuous compute time, computed as 97.4 seconds multiplied by 100,000 divided by 3,600 seconds per hour divided by 24 hours per day, demonstrating the intractability of full simulation for such workloads.

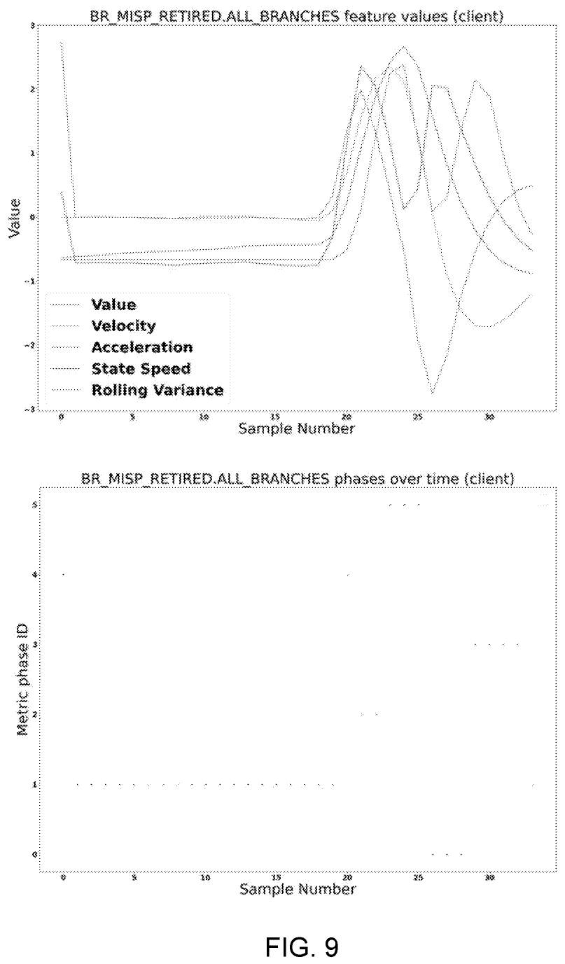

FIG. 9 illustrates an example of feature evolution and phase classification for a BR_MISP_RETIRED.ALL_BRANCHES hardware performance counter metric measured during the execution of an FFT workload. The left panel of FIG. 9 shows the normalized values of the five features, filtered counter value, trend estimate, trend difference, state speed, and rolling variance, plotted as a function of sample number over the 34 collected samples. The right panel of FIG. 9 shows the resulting metric-local phase identifiers assigned by k-means clustering after silhouette-optimized cluster count selection; out of the 34 total samples, 6 distinct metric-local phases were identified. The feature evolution illustrates three temporal regions. The initial samples, samples 0 through 2, are consumed by state estimation filter stabilization and carry unreliable feature values; these samples should not be used for phase detection. Samples 3 through 17 reflect operating system and process startup effects, which manifest as relatively steady feature values; these samples could be used in further refinements to compensate for initialization-phase noise. Samples 17 through 33 correspond to actual application execution and are information-rich for phase detection, exhibiting the full range of feature variation that distinguishes the phases. The features show non-equivalent time-varying characteristics, confirming that the multi-dimensional representation captures distinct aspects of workload behavior that no single feature alone conveys. Hardware performance counter metrics that are highly correlated may carry redundant phase-discrimination information; in such cases, a subset of metrics may be excluded from the phase detection pipeline to reduce data acquisition requirements and the circuit area of any hardware implementation.

In an example, the processor 210 comprises dedicated digital logic configured to implement the state estimation filter as a streaming pipeline processing one time point per sampling interval of hardware performance counters of the physical processor. The dedicated digital logic may further be configured to store state estimation outputs in model-specific registers, generate a phase-change status indicator upon detection of a transition between distinct execution phases, issue a phase-detection interrupt upon a phase change, and output phase-tagged records associating each time point with a corresponding phase identifier. In an example, the dedicated digital logic may be integrated within the existing PMU silicon of the physical processor, forming a hardware extension to the PMU that operates on hardware performance counter streams without requiring counter data to be exported to general-purpose processor cores for analysis. A model-specific register refers to a processor register accessible via privileged instructions and used to store intermediate or final results produced by the dedicated digital logic. The dedicated digital logic may further output CPUID feature flags indicating hardware phase detection capabilities, and generate phase-tagged Processor Event-Based Sampling (PEBS) records containing phase ID annotations alongside counter values.

In an alternative, the dedicated digital logic may be implemented as a dedicated co-processor on the same processor die as the physical processor, communicating with the PMU via an internal bus. Both alternatives enable the phase detection pipeline 300 to operate at one-sample throughput, processing one time point per PMU sampling interval, with pipeline latency bounded by the sampling interval. The two-by-two state estimation filter at the core of the hardware implementation is computationally inexpensive, requiring only a two-by-two matrix multiply and a scalar inverse at each time step, making it suitable for implementation as fixed-function digital logic. The five-dimensional feature vector computation may require access to two consecutive state vectors in register storage and a rolling buffer of five samples for the variance computation, both of which are directly implementable in hardware registers. The dedicated digital logic enables real-time control decisions, including dynamic voltage and frequency scaling, cache partitioning, prefetcher tuning, and power management, to be triggered by phase-detection interrupts during native workload execution.

In the embodiment of the system, the system, in addition to the device 200, may further include the architectural simulator. The architectural simulator may be configured to receive the one or more machine-readable control instructions and to simulate the software workload at varying fidelity levels according to the execution boundaries. The one or more hardware components may be the PMU of the physical processor, which generates hardware performance counter streams natively as the software workload executes. The system may be embodied as a single computing system in which the physical processor, the one or more processing units, and the architectural simulator all reside on the same hardware. The system may alternatively be embodied as a distributed configuration in which measurement hardware, one or more processing units performing analysis, and the architectural simulator reside on separate computing nodes communicating via a network such as the network 190 of FIG. 1. In a further alternative, the one or more processing units comprise the dedicated digital logic within the PMU described above with reference to FIG. 4, with the architectural simulator running on a separate computing node.

The one or more processing units of the system may be realized in a variety of configurations to cover the full range of deployment environments. The one or more processing units may comprise general-purpose processor cores of the physical processor executing the phase detection pipeline 300 in software on idle or reserved cores, enabling the physical processor to perform its own phase analysis during execution of the software workload. The one or more processing units may alternatively comprise a separate server or workstation receiving the time-series hardware performance counter data from the physical processor via the communication interface 230 and performing the state estimation filtering, feature extraction, clustering, and machine-readable control instruction generation on the received data. The one or more processing units may further comprise the dedicated digital logic within or adjacent to the PMU as described above with reference to FIG. 4, implementing the state estimation filter, feature computation, cluster distance computation, and phase detection as a streaming hardware pipeline. The one or more processing units may additionally comprise a heterogeneous combination, for example, the Kalman Filter Unit 420 and Feature Compute unit 430 implemented as dedicated digital logic while the clustering and control instruction generation execute on general-purpose processor cores. The flexibility of the one or more processing units enables the system to be adapted from embedded processor deployments to large-scale data center installations without changes to the phase detection pipeline structure or the machine-readable control instruction format consumed by the architectural simulator.

In an example, the system is applicable across multiple simulation and processor management domains. In a first domain, the system may support full-system simulation by enabling intelligent switching between fast functional simulation modes and detailed cycle-accurate timing simulation. This support in the first domain may include architectural simulators that support multiple timing modes, which may include in-order and stalling execution models parameterized by instructions per cycle or cycles per instruction, benefit from phase detection by confining detailed simulation to representative execution phases while traversing inter-phase intervals in fast functional mode, reducing synchronization time to phase-transition boundaries only. In a second domain, the system may support microarchitectural design-space exploration. This support of the second domain may include cycle-accurate architectural simulators operating on representative execution phases rather than the full workload trace enable evaluation of cache and memory hierarchy configurations, branch-prediction policies, and prefetcher designs across representative workload behavioral phases within practical compute time budgets. In a third domain, the system may support real-time processor control when the one or more processing units comprise dedicated digital logic within the PMU. This support may include the phase-detection interrupts and phase-change status indicators generated by the Phase Detector unit 450 enable dynamic voltage and frequency scaling, cache partitioning, prefetcher tuning, workload scheduling, and power management decisions to be triggered at phase boundaries during native execution. In a fourth domain, the system may support cloud and data center resource management by enabling phase-aware workload scheduling through phase-aware job placement and migration, predictive power capping through identification of high-power execution phases before they occur, and service level agreement management through identification of execution phases that risk service level agreement violations.

The architectural simulator of the system may select among varying fidelity levels according to the execution boundaries specified in the machine-readable control instructions. The fidelity levels available to the architectural simulator include a fast-forward mode in which instructions are executed functionally without pipeline modeling, a warm-up mode in which instructions are executed with sufficient pipeline modeling to initialize microarchitectural state including cache contents and branch-predictor tables, and a detailed-simulation mode in which instructions are executed with a complete cycle-accurate pipeline model collecting timing metrics including instructions per cycle, cache miss rates, and branch misprediction rates. The warm-up mode may be parameterized by configurable step rates expressed as instructions per cycle or cycles per instruction, enabling the degree of microarchitectural state initialization to be traded off against warm-up duration. The phase detection pipeline 300 enables the architectural simulator to allocate detailed-simulation resources exclusively to the representative execution phases identified by the phase detection pipeline 300, using warm-up or fast-forward mode to traverse the intervals between representative phases.

In some examples, the FFT benchmark workload exhibits three distinct execution phases observable at fine temporal resolution. A memory-bound phase spans the first approximately 10 milliseconds of execution, during which the workload accesses large data arrays with poor cache locality and the dominant bottleneck is data memory bandwidth. A compute-bound phase spans approximately 10 to 35 milliseconds, during which the workload performs the primary floating-point computation with high data reuse and the dominant bottleneck is arithmetic throughput. A communication or synchronization-bound phase spans approximately 35 to 50 milliseconds, during which the workload transfers partial results and synchronizes between computational tasks. The FFT execution additionally exhibits approximate periodicity, such that the second half of the execution trace closely, but not precisely, repeats the behavioral pattern of the first period, consistent with the structure of the FFT algorithm. Hardware measurements of the same FFT workload collected at a sampling interval of approximately 100 milliseconds can show significantly reduced behavioral dynamics compared to simulation data collected at a 1-millisecond sampling interval, because the 100-millisecond hardware sampling interval is coarser than the duration of several sub-phases visible at finer resolution. This temporal frequency aliasing causes intermediate sub-phases to appear merged in the hardware-measured time-series hardware performance data. The aliasing effect establishes that hardware-measured phase detection at 100-millisecond intervals identifies macro-phases of the workload rather than all micro-phases visible at finer temporal resolution, and confirms that further improvements in the integration of PMU hardware and software metrology are required to improve the observability of fine-grained workload phases from hardware measurements.

In an example, the phase detection pipeline 300 may be integrated with power and thermal simulation models to support coupled energy consumption estimation. Full-system simulation architectures that combine functional performance simulation with power and thermal modeling may require accurate knowledge of both the simulated instruction count and the simulated time elapsed for each simulation interval. The machine-readable control instructions generated by the processor 210 provide the execution boundaries and instruction counts needed to determine the simulated duration of each representative execution phase, enabling coupled power and thermal simulation at phase granularity. Simulation architectures with modular components, which may include separate functional execution, performance timing, and power/thermal modeling modules, can benefit from the phase detection pipeline 300 by reducing inter-module synchronization to phase-transition boundaries only. Rather than synchronizing at every simulation step, the modeling modules synchronize only when the phase changes, reducing synchronization overhead proportionally to the number of distinct execution phases. The machine-readable control instructions further enable each modeling module to apply phase-specific simulation fidelity: fast surrogate models may be used for execution phases that have been previously characterized, while cycle-accurate models are applied only to novel or representative phases requiring full analysis. The phase-tagged records output by the dedicated digital logic of the hardware implementation embodiment may additionally be used to generate phase-level power consumption traces in real time during native execution, enabling power management decisions at phase granularity without simulation overhead.

In an example, the intractability of full cycle-accurate simulation for long-running workloads may be quantified concretely. At a simulation slowdown of 100,000×, e.g., within the range of 100,000× to 500,000× characteristic of cycle-accurate architectural simulation, a software workload with a native execution duration of approximately 97.4 seconds, such as the MongoDB database benchmark described above, would require approximately 113 days of continuous compute time for complete cycle-accurate simulation, computed as 97.4 seconds multiplied by 100,000 divided by 3,600 seconds per hour divided by 24 hours per day. At the upper end of the slowdown range at 500,000×, the same workload would require approximately 565 days. These simulation durations are intractable in commercial architectural design settings, where multiple candidate processor configurations must each be evaluated against portfolios of representative workloads within design iteration timelines measured in days to weeks. The intractability can be compounded by practical challenges beyond duration alone: simulation of long workloads requires stable checkpoint mechanisms to recover from simulation process failures, generates large volumes of simulation output data requiring substantial storage infrastructure, and incurs high computational resource costs when run across portfolios of benchmarks. The phase-based simulation approach of the system addresses these challenges by reducing the simulated portion of the workload to a small number of representative execution phases, in the MongoDB example, 5 representative samples from 974 total, achieving a 194.8× reduction—converting simulation durations from months to hours and making iterative architectural evaluation of long-running server workloads practical within typical design timelines.

In an example, a system-level embodiment comprises a first computing device that hosts the physical processor and its associated PMU, which collects the time-series hardware performance counter data during native execution of the software workload on the physical processor; a second computing device, which may be the same physical device as the first computing device or a separate computing device, that performs various aspects described herein for the device (e.g., executes the phase detection pipeline 300, applying the state estimation filter, feature extraction, clustering, and machine-readable control instruction generation to the time-series hardware performance counter data received from the first computing device); and a third computing device, which may be the same as or different from the first and second computing devices, that hosts the architectural simulator and receives the machine-readable control instructions from the second computing device, simulating the representative execution phases of the software workload at varying fidelity levels. The three computing devices may communicate via the network 190 of FIG. 1 when deployed as separate nodes, or may be co-located as software processes on a single hardware platform. In a specific deployment, the first and second computing devices are the same physical device, enabling the physical processor to generate and locally analyze its own time-series hardware performance counter data, while a separate simulation server operates as the third computing device performing cycle-accurate simulation in parallel. The embodiments described herein encompass all combinations of the first, second, and third computing devices being the same device, distinct devices, or any intermediate configuration.

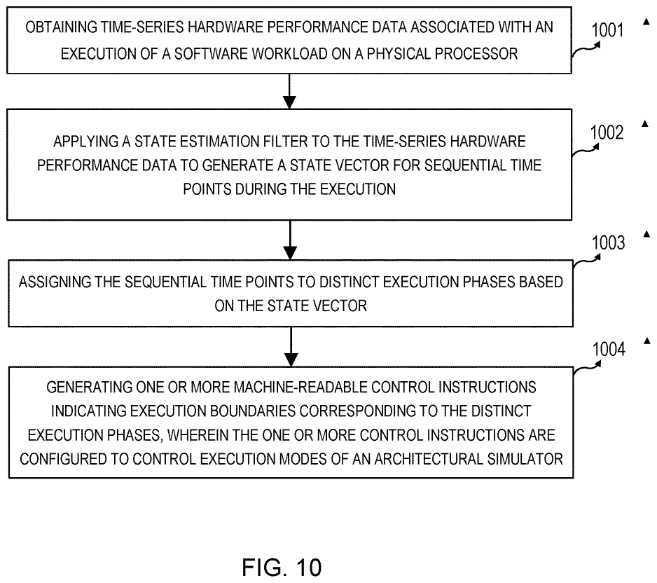

FIG. 10 shows an example of a method. The method includes obtaining 1001 time-series hardware performance data associated with an execution of a software workload on a physical processor; applying 1002 a state estimation filter to the time-series hardware performance data to generate a state vector for sequential time points during the execution; assigning 1003 the sequential time points to distinct execution phases based on the state vector; and generating 1004 one or more machine-readable control instructions indicating execution boundaries corresponding to the distinct execution phases, wherein the one or more control instructions are configured to control execution modes of an architectural simulator. A non-transitory computer-readable medium comprises instructions which, if executed by a processor, cause the processor to perform the method.

The following examples pertain to further aspects described herein.

Example 1 includes the subject matter of a device including: a memory, and processor configured to: obtain time-series hardware performance data associated with an execution of a software workload on a physical processor; apply a state estimation filter to the time-series hardware performance data to generate a state vector for sequential time points during the execution; assign the sequential time points to distinct execution phases based on the state vector; and generate one or more machine-readable control instructions indicating execution boundaries corresponding to the distinct execution phases, wherein the one or more control instructions are configured to control execution modes of an architectural simulator.

Example 2 may include the subject matter of example 1, wherein the state estimation filter is a recursive filter that maintains a joint state including a filtered counter value and a trend estimate, and wherein the joint state is updated at each successive time point using a dynamical model in which the filtered counter value at a next time point is predicted based on a current filtered counter value and a current trend estimate.

Example 3 may include the subject matter of any one of examples 1 to 2, wherein the processor is configured to assign the sequential time points to distinct execution phases by computing, for each time point, a multi-dimensional feature vector derived from at least the state vector, and applying a clustering algorithm to the multi-dimensional feature vectors to determine a cluster label for each time point, each distinct cluster label corresponding to a distinct execution phase.

Example 4 may include the subject matter of example 3, wherein the multi-dimensional feature vector for each time point includes at least two of: a filtered counter value from the state vector; a trend estimate from the state vector; a difference between the trend estimate at the time point and the trend estimate at an immediately preceding time point; a Euclidean norm of a vector including the difference in the filtered counter value and the difference in the trend estimate between the time point and the immediately preceding time point; or a variance of the filtered counter values within a sliding window of consecutive time points ending at the time point.

Example 5 may include the subject matter of example 4, wherein the multi-dimensional feature vector for each time point includes all five of: the filtered counter value, the trend estimate, the difference between trend estimates at successive time points, the Euclidean norm of the state vector difference, and the variance of filtered counter values within the sliding window.

Example 6 may include the subject matter of any one of examples 4 to 5, wherein the time-series hardware performance data includes a plurality of hardware performance counter metrics, wherein the processor is configured to: apply the state estimation filter independently to each hardware performance counter metric; assign a cluster label to each time point for each metric; and assign each time point to a distinct execution phase based on a concatenation of the cluster labels across all hardware performance counter metrics at that time point.

Example 7 may include the subject matter of any one of examples 4 to 6, wherein the processor is further configured to normalize the multi-dimensional feature vectors, dimension-by-dimension, by subtracting a mean value and dividing by a standard deviation, each computed across a window of time points, prior to applying the clustering algorithm.

Example 8 may include the subject matter of any one of examples 4 to 7, wherein the processor is configured to determine a number of clusters for the clustering algorithm by applying the clustering algorithm for each candidate number of clusters within a predefined range, computing a score for each candidate number of clusters based on intra-cluster and inter-cluster distances of the multi-dimensional feature vectors, and selecting the candidate number of clusters yielding the highest score, wherein the score includes a silhouette score or another measure of cluster cohesion and separation.

Example 9 may include the subject matter of any one of examples 1 to 8, wherein the processor is further configured to prepare the time-series hardware performance data by one or more of: summing hardware performance counter values across a plurality of processor cores to produce a per-time-point aggregate value; computing a running sum of the hardware performance counter values over successive time points prior to applying the state estimation filter; or applying a moving average filter to the time-series hardware performance data prior to applying the state estimation filter.

Example 10 may include the subject matter of any one of examples 1 to 9, wherein the execution boundaries are expressed as instruction counts derived from a cumulative value of a retired-instruction counter of the physical processor, each execution boundary indicating a start offset and a duration in terms of instruction counts.

Example 11 may include the subject matter of any one of examples 1 to 10, wherein the one or more control instructions indicate, for each distinct execution phase, a warm-up interval followed by a detailed-simulation interval, the warm-up interval representing a number of instructions for execution at reduced simulation fidelity before the detailed-simulation interval commences.

Example 12 may include the subject matter of any one of examples 1 to 11, wherein the processor is configured to select a single representative time point for each distinct execution phase and to generate the one or more control instructions to indicate execution boundaries corresponding to the representative time points, wherein the representative time points are selected based on one or more selection criteria comprising an early occurrence within the corresponding execution phase.

Example 13 may include the subject matter of any one of examples 1 to 12, wherein the time-series hardware performance data includes first hardware performance counter data collected from a first set of processor cores assigned to a first process and second hardware performance counter data collected from a second set of processor cores assigned to a second process, and wherein the processor is configured to temporally align the first and second hardware performance counter data by resampling to a common time base prior to applying the state estimation filter, and to apply the state estimation filter independently to the aligned first and second hardware performance counter data and to assign each time point to a distinct execution phase based on state vectors derived from both the first and second hardware performance counter data.

Example 14 may include the subject matter of any one of examples 1 to 13, wherein the processor is further configured to: reconstruct an estimated time-series of a hardware performance counter metric by, for each execution phase, linearly interpolating between sampled counter values at boundaries of the execution phase across all time points within that execution phase; and evaluate reconstruction accuracy by computing at least one of a normalized root mean square error, a cross-correlation coefficient, a dynamic time warping distance, or a Kullback-Leibler divergence between the reconstructed estimated time-series and the time-series hardware performance data.

Example 15 may include the subject matter of any one of examples 1 to 14, wherein the processor includes dedicated digital logic configured to implement the state estimation filter as a streaming pipeline processing one time point per sampling interval of hardware performance counters of the physical processor, the dedicated digital logic further configured to store state estimation outputs in model-specific registers, generate a phase-change status indicator upon detection of a transition between distinct execution phases, issue a phase-detection interrupt upon a phase change, and output phase-tagged records associating each time point with a corresponding phase identifier.

Example 16 may include the subject matter of any one of examples 1 to 15, wherein the state estimation filter is configured to estimate its noise parameters from the time-series hardware performance data observed up to each current time point, without requiring access to future time points.

Example 17 may include the subject matter of any one of examples 1 to 16, wherein observation noise and process noise parameters of the state estimation filter are derived from statistical properties of the time-series hardware performance data computed over the entire observed time-series.

Example 18 may include the subject matter of any one of examples 1 to 17, may further include the architectural simulator configured to receive the one or more control instructions from the processor and to simulate the software workload by switching between execution modes according to the execution boundaries indicated by the one or more control instructions.

Example 19 may include the subject matter of any one of examples 1 to 18, wherein the processor is the same processor as the physical processor.

Example 20 may include a system for workload phase detection including: one or more hardware components configured to collect time-series hardware performance counter data from a physical processor executing a software workload; one or more processing units, wherein the one or more processing units are the same as or different from the physical processor, configured to: apply a state estimation filter to the time-series hardware performance counter data to generate a state vector for sequential time points during the execution; assign the sequential time points to distinct execution phases based on the state vector; and generate one or more machine-readable control instructions indicating execution boundaries corresponding to the distinct execution phases; and an architectural simulator configured to receive the one or more machine-readable control instructions and to simulate the software workload at varying fidelity levels according to the execution boundaries.

Example 21 includes the subject matter of a method including: obtaining time-series hardware performance data associated with an execution of a software workload on a physical processor; applying a state estimation filter to the time-series hardware performance data to generate a state vector for sequential time points during the execution; assigning the sequential time points to distinct execution phases based on the state vector; and generating one or more machine-readable control instructions indicating execution boundaries corresponding to the distinct execution phases, wherein the one or more control instructions are configured to control execution modes of an architectural simulator.

Example 22 may include the subject matter of example 21, wherein the state estimation filter is a recursive filter that maintains a joint state including a filtered counter value and a trend estimate, and wherein the joint state is updated at each successive time point using a dynamical model in which the filtered counter value at a next time point is predicted based on a current filtered counter value and a current trend estimate.

Example 23 may include the subject matter of any one of examples 21 to 22, wherein assigning the sequential time points to distinct execution phases includes computing, for each time point, a multi-dimensional feature vector derived from at least the state vector, and applying a clustering algorithm to the multi-dimensional feature vectors to determine a cluster label for each time point, each distinct cluster label corresponding to a distinct execution phase.

Example 24 may include the subject matter of example 23, wherein the multi-dimensional feature vector for each time point includes at least two of: a filtered counter value from the state vector; a trend estimate from the state vector; a difference between the trend estimate at the time point and the trend estimate at an immediately preceding time point; a Euclidean norm of a vector including the difference in the filtered counter value and the difference in the trend estimate between the time point and the immediately preceding time point; or a variance of the filtered counter values within a sliding window of consecutive time points ending at the time point.

Example 25 may include the subject matter of example 24, wherein the multi-dimensional feature vector for each time point includes all five of: the filtered counter value, the trend estimate, the difference between trend estimates at successive time points, the Euclidean norm of the state vector difference, and the variance of filtered counter values within the sliding window.

Example 26 may include the subject matter of any one of examples 24 to 25, wherein the time-series hardware performance data includes a plurality of hardware performance counter metrics, the method may further include: applying the state estimation filter independently to each hardware performance counter metric; assigning a cluster label to each time point for each metric; and assigning each time point to a distinct execution phase based on a concatenation of the cluster labels across all hardware performance counter metrics at that time point.

Example 27 may include the subject matter of any one of examples 24 to 26, may further include normalizing the multi-dimensional feature vectors, dimension-by-dimension, by subtracting a mean value and dividing by a standard deviation, each computed across a window of time points, prior to applying the clustering algorithm.

Example 28 may include the subject matter of any one of examples 24 to 27, may further include determining a number of clusters for the clustering algorithm by applying the clustering algorithm for each candidate number of clusters within a predefined range, computing a score for each candidate number of clusters based on intra-cluster and inter-cluster distances of the multi-dimensional feature vectors, and selecting the candidate number of clusters yielding the highest score, wherein the score includes a silhouette score or another measure of cluster cohesion and separation.

Example 29 may include the subject matter of any one of examples 21 to 28, may further include preparing the time-series hardware performance data by one or more of: summing hardware performance counter values across a plurality of processor cores to produce a per-time-point aggregate value; computing a running sum of the hardware performance counter values over successive time points prior to applying the state estimation filter; or applying a moving average filter to the time-series hardware performance data prior to applying the state estimation filter.

Example 30 may include the subject matter of any one of examples 21 to 29, wherein the execution boundaries are expressed as instruction counts derived from a cumulative value of a retired-instruction counter of the physical processor, each execution boundary indicating a start offset and a duration in terms of instruction counts.

Example 31 may include the subject matter of any one of examples 21 to 30, wherein the one or more control instructions indicate, for each distinct execution phase, a warm-up interval followed by a detailed-simulation interval, the warm-up interval representing a number of instructions for execution at reduced simulation fidelity before the detailed-simulation interval commences.

Example 32 may include the subject matter of any one of examples 21 to 31, may further include selecting a single representative time point for each distinct execution phase and generating the one or more control instructions to indicate execution boundaries corresponding to the representative time points, wherein the representative time points are selected based on one or more selection criteria comprising an early occurrence within the corresponding execution phase.

Example 33 may include the subject matter of any one of examples 21 to 32, wherein the time-series hardware performance data includes first hardware performance counter data collected from a first set of processor cores assigned to a first process and second hardware performance counter data collected from a second set of processor cores assigned to a second process, the method may further include: temporally aligning the first and second hardware performance counter data by resampling to a common time base prior to applying the state estimation filter; applying the state estimation filter independently to the aligned first and second hardware performance counter data; and assigning each time point to a distinct execution phase based on state vectors derived from both the first and second hardware performance counter data.

Example 34 may include the subject matter of any one of examples 21 to 33, may further include: reconstructing an estimated time-series of a hardware performance counter metric by, for each execution phase, linearly interpolating between sampled counter values at boundaries of the execution phase across all time points within that execution phase; and evaluating reconstruction accuracy by computing at least one of a normalized root mean square error, a cross-correlation coefficient, a dynamic time warping distance, or a Kullback-Leibler divergence between the reconstructed estimated time-series and the time-series hardware performance data.

Example 35 may include the subject matter of any one of examples 21 to 34, wherein applying the state estimation filter is performed as a streaming pipeline processing one time point per sampling interval of hardware performance counters of the physical processor, the method may further include: storing state estimation outputs in model-specific registers; generating a phase-change status indicator upon detection of a transition between distinct execution phases; issuing a phase-detection interrupt upon a phase change; and outputting phase-tagged records associating each time point with a corresponding phase identifier.

Example 36 may include the subject matter of any one of examples 21 to 35, may further include estimating noise parameters of the state estimation filter from the time-series hardware performance data observed up to each current time point, without requiring access to future time points.

Example 37 may include the subject matter of any one of examples 21 to 36, wherein observation noise and process noise parameters of the state estimation filter are derived from statistical properties of the time-series hardware performance data computed over the entire observed time-series.

Example 38 may include the subject matter of any one of examples 21 to 37, may further include receiving the one or more control instructions at the architectural simulator and simulating the software workload by switching between execution modes according to the execution boundaries indicated by the one or more control instructions.

Example 39 may include the subject matter of any one of examples 21 to 38, wherein the method is performed by the physical processor executing the software workload.

Example 40 may include A method for workload phase detection including: collecting time-series hardware performance counter data from a physical processor executing a software workload; applying a state estimation filter to the time-series hardware performance counter data to generate a state vector for sequential time points during the execution; assigning the sequential time points to distinct execution phases based on the state vector; generating one or more machine-readable control instructions indicating execution boundaries corresponding to the distinct execution phases; receiving the one or more machine-readable control instructions at an architectural simulator; and simulating the software workload at varying fidelity levels according to the execution boundaries using the architectural simulator.

Example 41 may include a non-transitory computer-readable medium including instructions which, if executed by a processor, cause the processor to perform the method of any one of examples 21 to 40.

Example 42 may include an apparatus including means to perform the method of any one of examples 21 to 40.

The word “exemplary” is used herein to mean “serving as an example, instance, or illustration”. Any embodiment or design described herein as “exemplary” is not necessarily to be construed as preferred or advantageous over other embodiments or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

Any vector and/or matrix notation utilized herein is exemplary in nature and is employed solely for purposes of explanation. Accordingly, the apparatuses and methods of described herein accompanied by vector and/or matrix notation are not limited to being implemented solely using vectors and/or matrices, and that the associated processes and computations may be equivalently performed with respect to sets, sequences, groups, etc., of data, observations, information, signals, samples, symbols, elements, etc.

As used herein, “memory” is understood as a non-transitory computer-readable medium in which data or information can be stored for retrieval. References to “memory” included herein may thus be understood as referring to volatile or non-volatile memory, including random access memory (“RAM”), read-only memory (“ROM”), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

In the context described herein, the term “process” may be used, for example, to indicate a method. Illustratively, any process described herein may be implemented as a method (e.g., a channel estimation process may be understood as a channel estimation method). Any process described herein may be implemented as a non-transitory computer readable medium including instructions configured, when executed, to cause one or more processors to carry out the process (e.g., to carry out the method).

Throughout the drawings, it should be noted that like reference numbers are used to depict the same or similar elements, features, and structures, unless otherwise noted. It should be noted that certain components may be omitted for the sake of simplicity. It should be noted that nodes (dots) are provided to identify the circuit line intersections in the drawings including electronic circuit diagrams.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

As used herein, a signal or information that is “indicative of”, “representative”, “representing”, or “indicating” a value or other information may be a digital or analog signal that encodes or otherwise, communicates the value or other information in a manner that can be decoded by and/or cause a responsive action in a component receiving the signal. The signal may be stored or buffered in computer-readable storage medium prior to its receipt by the receiving component and the receiving component may retrieve the signal from the storage medium. Further, a “value” that is “indicative of “or “representative” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, central processing unit (CPU), graphics processing unit (GPU), neural processing unit (NPU), digital signal processor (DSP), field programmable gate array (FPGA), integrated circuit, application specific integrated circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The terms “one or more processors” is intended to refer to a processor or a controller. The one or more processors may include one processor or a plurality of processors. The terms are simply used as an alternative to the “processor” or “controller”.

As utilized herein, terms “module”, “component,” “system,” “circuit,” “element,” “slice,” “circuit,” and the like are intended to refer to a set of one or more electronic components, a computer-related entity, hardware, software (e.g., in execution), and/or firmware. For example, circuit or a similar term can be a processor, a process running on a processor, a controller, an object, an executable program, a storage device, and/or a computer with a processing device. By way of illustration, an application running on a server and the server can also be circuit. One or more circuits can reside within the same circuit, and circuit can be localized on one computer and/or distributed between two or more computers. A set of elements or a set of other circuits can be described herein, in which the term “set” can be interpreted as “one or more”.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. The term “data item” may include data or a portion of data.

It will be understood that when an element is referred to as being “connected” or “coupled” to another element, it can be physically connected or coupled to the other element such that current and/or electromagnetic radiation (e.g., a signal) can flow along a conductive path formed by the elements. Inherently, such element is connectable or couplable to the another element. Intervening conductive, inductive, or capacitors may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “provided” to an element, the voltage, current, or signal may be conducted to the element by way of a physical connection or by way of capacitive, electro-magnetic, or inductive coupling that does not involve a physical connection.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as radio frequency transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method. All acronyms defined in the above description additionally hold in all claims included herein.

What is claimed is:

1. A device comprising: a memory, and processor configured to:
obtain time-series hardware performance data associated with an execution of a software workload on a physical processor;
apply a state estimation filter to the time-series hardware performance data to generate a state vector for sequential time points during the execution;
assign the sequential time points to distinct execution phases based on the state vector; and
generate one or more machine-readable control instructions indicating execution boundaries corresponding to the distinct execution phases, wherein the one or more control instructions are configured to control execution modes of an architectural simulator.

2. The device of claim 1, wherein the state estimation filter is a recursive filter that maintains a joint state comprising a filtered counter value and a trend estimate, and wherein the joint state is updated at each successive time point using a dynamical model in which the filtered counter value at a next time point is predicted based on a current filtered counter value and a current trend estimate.

3. The device of claim 1, wherein the processor is configured to assign the sequential time points to distinct execution phases by computing, for each time point, a multi-dimensional feature vector derived from at least the state vector, and applying a clustering algorithm to the multi-dimensional feature vectors to determine a cluster label for each time point, each distinct cluster label corresponding to a distinct execution phase.

4. The device of claim 3, wherein the multi-dimensional feature vector for each time point comprises at least two of: a filtered counter value from the state vector; a trend estimate from the state vector; a difference between the trend estimate at the time point and the trend estimate at an immediately preceding time point; a Euclidean norm of a vector comprising the difference in the filtered counter value and the difference in the trend estimate between the time point and the immediately preceding time point; or a variance of the filtered counter values within a sliding window of consecutive time points ending at the time point.

5. The device of claim 4, wherein the multi-dimensional feature vector for each time point comprises all five of: the filtered counter value, the trend estimate, the difference between trend estimates at successive time points, the Euclidean norm of the state vector difference, and the variance of filtered counter values within the sliding window.

6. The device of claim 4, wherein the time-series hardware performance data comprises a plurality of hardware performance counter metrics,
wherein the processor is configured to:
apply the state estimation filter independently to each hardware performance counter metric;
assign a cluster label to each time point for each metric; and
assign each time point to a distinct execution phase based on a concatenation of the cluster labels across all hardware performance counter metrics at that time point.

7. The device of claim 4, wherein the processor is further configured to normalize the multi-dimensional feature vectors, dimension-by-dimension, by subtracting a mean value and dividing by a standard deviation, each computed across a window of time points, prior to applying the clustering algorithm.

8. The device of claim 4, wherein the processor is configured to determine a number of clusters for the clustering algorithm by applying the clustering algorithm for each candidate number of clusters within a predefined range, computing a score for each candidate number of clusters based on intra-cluster and inter-cluster distances of the multi-dimensional feature vectors, and selecting the candidate number of clusters yielding the highest score, wherein the score comprises a silhouette score or another measure of cluster cohesion and separation.

9. The device of claim 1, wherein the processor is further configured to prepare the time-series hardware performance data by one or more of:
summing hardware performance counter values across a plurality of processor cores to produce a per-time-point aggregate value;
computing a running sum of the hardware performance counter values over successive time points prior to applying the state estimation filter; or
applying a moving average filter to the time-series hardware performance data prior to applying the state estimation filter.

10. The device of claim 1, wherein the execution boundaries are expressed as instruction counts derived from a cumulative value of a retired-instruction counter of the physical processor, each execution boundary indicating a start offset and a duration in terms of instruction counts.

11. The device of claim 1, wherein the one or more control instructions indicate, for each distinct execution phase, a warm-up interval followed by a detailed-simulation interval, the warm-up interval representing a number of instructions for execution at reduced simulation fidelity before the detailed-simulation interval commences.

12. The device of claim 1, wherein the processor is configured to select a single representative time point for each distinct execution phase and to generate the one or more control instructions to indicate execution boundaries corresponding to the representative time points,
wherein the representative time points are selected based on one or more selection criteria comprising an early occurrence within the corresponding execution phase.

13. The device of claim 1, wherein the time-series hardware performance data comprises first hardware performance counter data collected from a first set of processor cores assigned to a first process and second hardware performance counter data collected from a second set of processor cores assigned to a second process, and
wherein the processor is configured to temporally align the first and second hardware performance counter data by resampling to a common time base prior to applying the state estimation filter, and to apply the state estimation filter independently to the aligned first and second hardware performance counter data and to assign each time point to a distinct execution phase based on state vectors derived from both the first and second hardware performance counter data.

14. The device of claim 1, wherein the processor comprises dedicated digital logic configured to implement the state estimation filter as a streaming pipeline processing one time point per sampling interval of hardware performance counters of the physical processor, the dedicated digital logic further configured to store state estimation outputs in model-specific registers, generate a phase-change status indicator upon detection of a transition between distinct execution phases, issue a phase-detection interrupt upon a phase change, and output phase-tagged records associating each time point with a corresponding phase identifier.

15. The device of claim 1, wherein the state estimation filter is configured to estimate noise parameters of the state estimation filter from the time-series hardware performance data observed up to each current time point, without requiring access to future time points.

16. The device of claim 1, wherein the processor is the same processor as the physical processor.

17. A system for workload phase detection comprising:
one or more hardware components configured to collect time-series hardware performance counter data from a physical processor executing a software workload;
one or more processing units configured to:
apply a state estimation filter to the time-series hardware performance counter data to generate a state vector for sequential time points during the execution;
assign the sequential time points to distinct execution phases based on the state vector; and
generate one or more machine-readable control instructions indicating execution boundaries corresponding to the distinct execution phases; and
an architectural simulator configured to receive the one or more machine-readable control instructions and to simulate the software workload at varying fidelity levels according to the execution boundaries.

18. The system of claim 17, wherein the one or more processing units comprises the physical processor.

19. A non-transitory computer-readable medium comprising instructions which, if executed by a processor, cause the processor to:
obtain time-series hardware performance data associated with an execution of a software workload on a physical processor;
apply a state estimation filter to the time-series hardware performance data to generate a state vector for sequential time points during the execution;
assign the sequential time points to distinct execution phases based on the state vector; and
generate one or more machine-readable control instructions indicating execution boundaries corresponding to the distinct execution phases, wherein the one or more control instructions are configured to control execution modes of an architectural simulator.

20. The non-transitory computer-readable medium of claim 19, wherein the architectural simulator is implemented by the processor.
